(19) United States
(12) Patent Application Publication
(10) Pub. No.: US 2009/0236727 A1
(43) Pub. Date: Sep. 24, 2009

(54) WIRING SUBSTRATE AND METHOD OF MANUFACTURING THE SAME, AND SEMICONDUCTOR DEVICE AND METHOD OF MANUFACTURING THE SAME

(75) Inventors: Kei MURAYAMA, Nagano-shi (JP); Masahiro Sunohara, Nagano-shi (JP); Hideaki Sakaguchi, Nagano-shi (JP); Mitsutoshi Higashi, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/408,853

(22) Filed: Mar. 23, 2009

(30) Foreign Application Priority Data
Mar. 24, 2008 (JP) P2008-076775

(51) Int. Cl. H01L 23/48; B32B 37/00

(52) U.S. Cl. 257/692; 156/247; 257/E23.01

(57) ABSTRACT

A wiring substrate is provided. The wiring substrate includes a multilayer wiring structure and a stiffener. The multilayer wiring structure includes: a plurality of insulating layers; a plurality of wiring patterns; and a plurality of chip mounting pads which are electrically connected to the wiring patterns and on which a semiconductor chip is flip-chip mounted. The stiffener is provided on a portion of the multilayer wiring structure, which is outside of a mounting area on which the semiconductor chip is flip-chip mounted. A thermal expansion coefficient of the stiffener is substantially equal to that of the semiconductor chip.

This application claims priority from Japanese Patent Application No. 2008-076775, filed on Mar. 24, 2008, the entire contents of which are incorporated by reference herein.

### BACKGROUND OF THE INVENTION

1. Technical Field

The present disclosure relates to a wiring substrate and a method of manufacturing the same and a semiconductor device and a method of manufacturing the same. More particularly, the present disclosure relates to a wiring substrate that includes a multilayer wiring structure on which a semiconductor chip is mounted and a stiffener provided on the multilayer wiring structure and a method of manufacturing the same and a semiconductor device and a method of manufacturing the same.

2. Related Art

A related-art semiconductor device (a semiconductor package) includes a semiconductor chip, and a wiring substrate having a multilayer wiring structure on which the semiconductor chip is flip-chip mounted and a stiffener that is adhered onto the multilayer wiring structure.

Also, the semiconductor chip includes a semiconductor substrate (e.g., a silicon substrate whose thermal expansion coefficient is 3 to 4 ppm/° C.), a semiconductor integrated circuit formed on the semiconductor substrate, and electrode pads electrically connected to the semiconductor integrated circuit.

Also, the multilayer wiring structure includes a resin layer laminated body in which a plurality of resin layers (whose thermal expansion coefficient is 55 ppm/° C.) are laminated, wiring patterns provided in the resin layer laminated body and electrically connected to the semiconductor chip, and chip mounting pads which are electrically connected to the wiring patterns and on which the semiconductor chip is mounted. As the multilayer wiring structure, for example, the coreless substrate can be employed. When the coreless substrate is used as the multilayer wiring structure, the multilayer wiring structure is formed by forming the multilayer wiring structure on the Cu plate (whose thermal expansion coefficient is 18 ppm/° C.) acting as a support by the build-up method and then removing the Cu plate by etching. In the build-up method, a heating process and a cooling process are repeatedly applied.

The stiffener has a through hole that accommodates the semiconductor chip mounted on the multilayer wiring structure. The stiffener is the member that is provided to reduce a warp and a distortion of the coreless substrate. The stiffener is formed by different manufacturing steps from those applied to the multilayer wiring structure, and is adhered to the multilayer wiring structure from which the Cu plate as the support is removed by the adhesive. As the material of the stiffener, a metal such as Ni, Cu may be employed (see JP-A-2000-323613, for example).

However, in the related art semiconductor device, a thermal expansion coefficient of the semiconductor chip is different from that of the stiffener made of the metal. Therefore, for example, when the semiconductor device is mounted on a mounting substrate such as a motherboard, the multilayer wiring structure is expanded and contracted by heating applied during mounting and thus reliability of the electric connection between the semiconductor device and the mounting substrate is decreased.

Also, in the related art method of manufacturing the wiring substrate, a thermal expansion coefficient of the Cu plate as the support is large (a thermal expansion coefficient of the Cu plate as the support is 18 ppm/° C.). Therefore, a warp and a distortion of the multilayer wiring structure caused upon manufacturing the multilayer wiring structure (concretely, a warp and a distortion caused due to a difference in thermal expansion coefficient between the resin layers and the Cu plate) cannot be sufficiently suppressed. As a result, such a problem existed that reliability of the electric connection between the semiconductor chip and the wiring substrate is decreased.

Also, in the related art method of manufacturing the wiring substrate, the stiffer is adhered to the multilayer wiring structure from which the Cu plate as the support is removed. Therefore, a warp and a distortion that are suppressed by the Cu plate are reflected to the multilayer wiring structure. Accordingly, positions of the chip mounting pads provided on the multilayer wiring structure formed on the Cu plate and positions of the chip mounting pads provided on the multilayer wiring structure from which the Cu plate is removed are misaligned. As a result, reliability of the electric connection between the semiconductor chip and the wiring substrate is decreased.

In this event, the above problems become more conspicuous in the case where the semiconductor chip whose electrode pads are arranged at a narrow pitch is mounted on the chip mounting pads of the multilayer wiring structure.

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any of the problems described above.

Accordingly, it is an aspect of the present invention to provide a wiring substrate and a method of manufacturing the same and a semiconductor device and a method of manufacturing the same, capable of improving reliability of the electric connection.

According to one or more aspects of the present invention, a wiring substrate is provided. The wiring substrate includes a multilayer wiring structure and a stiffener. The multilayer wiring structure includes: a plurality of insulating layers; a plurality of wiring patterns; and a plurality of chip mounting pads which are electrically connected to the wiring patterns and on which a semiconductor chip is flip-chip mounted. The stiffener is provided on a portion of the multilayer wiring structure, which is outside of a mounting area on which the semiconductor chip is flip-chip mounted. A thermal expansion coefficient of the stiffener is substantially equal to that of the semiconductor chip.

According to one or more aspects of the present invention, a semiconductor device is provided. The semiconductor device includes a semiconductor chip and a wiring substrate. The wiring substrate includes a multilayer wiring structure and a stiffener. The multilayer wiring structure includes: a plurality of insulating layers; a plurality of wiring patterns; and a plurality of chip mounting pads which are electrically connected to the wiring patterns and on which the semiconductor chip is flip-chip mounted. The stiffener is provided on a portion of the multilayer wiring structure, which is outside of a mounting area on which the semiconductor chip is flip-chip mounted, wherein a thermal expansion coefficient of the stiffener is substantially equal to that of the semiconductor chip.

According to one or more aspects of the present invention, there is a method of manufacturing a wiring substrate including a stiffener. The method includes: (a) forming a stiffener base material whose thermal expansion coefficient is substantially equal to that of a semiconductor chip and which has a through portion therein; (b) forming a support which has a convex portion corresponding to a shape of the through portion and whose thermal expansion coefficient is substantially equal to that of the semiconductor chip; (c) tentatively adhering the stiffener base material to the support by inserting the convex portion into the through portion; (d) forming a multilayer wiring structure over the convex portion and the stiffener base material; and (e) removing the support from the stiffener base material after step (d).

According to one or more aspects of the present invention, there is provided a method of manufacturing wiring substrates. The method includes: (a) forming a stiffener base material whose thermal expansion coefficient is substantially equal to that of a semiconductor chip and which has a plurality of through portions therein; (b) forming a support which has a plurality of convex portions each corresponding to a shape of a corresponding one of the through portions and whose thermal expansion coefficient is substantially equal to that of the semiconductor chip; (c) tentatively adhering the stiffener base material to the support by inserting the convex portions into the through portions; (d) forming a multilayer wiring structure over the convex portions and the stiffener base material; (e) removing the support from the stiffener base material after step (d); and (f) cutting the stiffener base material and the multilayer wiring structure after step (e), thereby forming the wiring substrates.

Other aspects and advantages of the present invention will be apparent from the following description, the drawings, and the claims.

### BRIEF DESCRIPTION OF THE DRAWINGS

FIG. 1 is a sectional view of a semiconductor device (semiconductor package) according to a first exemplary embodiment of the present invention;

FIG. 2 is a view (#1) showing steps of manufacturing the semiconductor device according to the first exemplary embodiment of the present invention;

FIG. 3 is a view (#2) showing steps of manufacturing the semiconductor device according to the first exemplary embodiment of the present invention;

FIG. 4 is a view (#3) showing steps of manufacturing the semiconductor device according to the first exemplary embodiment of the present invention;

FIG. 5 is a view (#4) showing steps of manufacturing the semiconductor device according to the first exemplary embodiment of the present invention;

FIG. 6 is a view (#5) showing steps of manufacturing the semiconductor device according to the first exemplary embodiment of the present invention;

FIG. 7 is a view (#6) showing steps of manufacturing the semiconductor device according to the first exemplary embodiment of the present invention;

FIG. 8 is a view (#7) showing steps of manufacturing the semiconductor device according to the first exemplary embodiment of the present invention;

FIG. 9 is a view (#8) showing steps of manufacturing the semiconductor device according to the first exemplary embodiment of the present invention;

FIG. 10 is a view (#9) showing steps of manufacturing the semiconductor device according to the first exemplary embodiment of the present invention;

FIG. 11 is a view (#10) showing steps of manufacturing the semiconductor device according to the first exemplary embodiment of the present invention;

FIG. 12 is a view (#11) showing steps of manufacturing the semiconductor device according to the first exemplary embodiment of the present invention;

FIG. 13 is a view (#12) showing steps of manufacturing the semiconductor device according to the first exemplary embodiment of the present invention;

FIG. 14 is a view (#13) showing steps of manufacturing the semiconductor device according to the first exemplary embodiment of the present invention;

FIG. 15 is a view (#14) showing steps of manufacturing the semiconductor device according to the first exemplary embodiment of the present invention;

FIG. 16 is a view (#15) showing steps of manufacturing the semiconductor device according to the first exemplary embodiment of the present invention;

FIG. 17 is a view (#16) showing steps of manufacturing the semiconductor device according to the first exemplary embodiment of the present invention;

FIG. 18 is a view (#17) showing steps of manufacturing the semiconductor device according to the first exemplary embodiment of the present invention;

FIG. 19 is a view (#18) showing steps of manufacturing the semiconductor device according to the first exemplary embodiment of the present invention;

FIG. 20 is a view (#19) showing steps of manufacturing the semiconductor device according to the first exemplary embodiment of the present invention;

FIG. 21 is a view (#20) showing steps of manufacturing the semiconductor device according to the first exemplary embodiment of the present invention;

FIG. 22 is a view (#21) showing steps of manufacturing the semiconductor device according to the first exemplary embodiment of the present invention;

FIG. 23 is a view (#22) showing steps of manufacturing the semiconductor device according to the first exemplary embodiment of the present invention;

FIG. 24 is a view (#23) showing steps of manufacturing the semiconductor device according to the first exemplary embodiment of the present invention;

FIG. 25 is a view (#24) showing steps of manufacturing the semiconductor device according to the first exemplary embodiment of the present invention;

FIG. 26 is a view (#25) showing steps of manufacturing the semiconductor device according to the first exemplary embodiment of the present invention;

FIG. 27 is a view explaining another stiffener base material;

FIG. 28 is a sectional view of a semiconductor device (semiconductor package) according to a second exemplary embodiment of the present invention;

FIG. 29 is a view (#1) showing steps of manufacturing the semiconductor device according to the second exemplary embodiment of the present invention;

FIG. 30 is a view (#2) showing steps of manufacturing the semiconductor device according to the second exemplary embodiment of the present invention;

FIG. 31 is a view (#3) showing steps of manufacturing the semiconductor device according to the second exemplary embodiment of the present invention;

FIG. 32 is a view (#4) showing steps of manufacturing the semiconductor device according to the second exemplary embodiment of the present invention;

FIG. 33 is a view (#5) showing steps of manufacturing the semiconductor device according to the second exemplary embodiment of the present invention;

FIG. 34 is a view (#6) showing steps of manufacturing the semiconductor device according to the second exemplary embodiment of the present invention;

FIG. 35 is a view (#7) showing steps of manufacturing the semiconductor device according to the second exemplary embodiment of the present invention;

FIG. 36 is a view (#8) showing steps of manufacturing the semiconductor device according to the second exemplary embodiment of the present invention; and

FIG. 37 is a view (#9) showing steps of manufacturing the semiconductor device according to the second exemplary embodiment of the present invention.

### DETAILED DESCRIPTION OF EXEMPLARY EMBODIMENTS OF THE INVENTION

Exemplary embodiments of the present invention will be now described with reference to the drawings hereinafter.

### First Embodiment

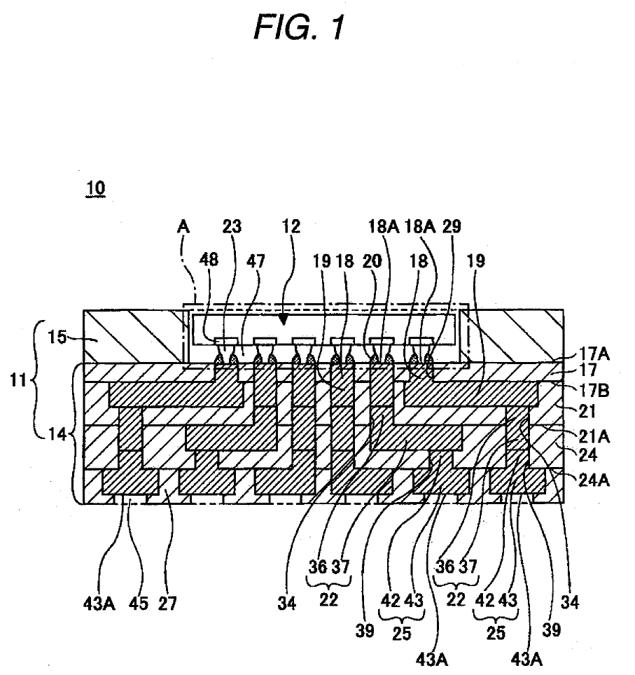

FIG. 1 is a sectional view of a semiconductor device (semiconductor package) according to a first exemplary embodiment of the present invention.

By reference to FIG. 1, a semiconductor device 10 of the first embodiment includes a wiring substrate 11 and semiconductor chip 12.

The wiring substrate 11 has a multilayer wiring structure 14 and a stiffener 15. The multilayer wiring structure 14 has insulating layers 17, 21 and 24 (a plurality of laminated insulating layers), chip connection pads 18, wiring patterns 19, 22 and 25, solders 20, and a solder resist layer 27.

The insulating layer 17 is a layer that is used to form the chip connection pads 18 on which the semiconductor chip 12 is mounted, and the wiring patterns 19. The insulating layer 17 has through holes 29. As the insulating layer 17, for example, a resin layer can be employed. As a material of the resin layer, for example, an epoxy resin, a polyimide resin or the like can be employed.

The chip connection pad 18 is provided in the through holes 29 respectively. The chip connection pads 18 are integrally formed with the wiring patterns 19. The chip connection pads 18 are pads that are used to flip-chip mount the semiconductor chip 12, and electrically connected to the semiconductor chip 12. Also, connection surfaces 18A of the chip connection pads 18 are almost flush with a surface 17A of the insulating layer 17. The solder 20 is formed on the connection surfaces 18A of the chip connection pads 18 respectively. As the material of the chip connection pads 18, for example, Cu can be employed.

The wiring patterns 19 are provided on a surface 17B of the insulating layer 17 (a surface of the insulating layer 17 on the opposite side to the surface 17A). The wiring patterns 19 are electrically connected to the chip connection pads 18. As the material of the wiring patterns 19, for example, Cu can be employed.

The solder 20 is provided on the connection surfaces 18A of the chip connection pads 18 respectively. The solder 20 is used to secure bumps 23 provided on electrode pads 48 of the semiconductor chip 12 onto the chip connection pads 18. As the solder 20, for example, Sn—Ag—Cu based solder, Sn—Zn—Bi based solder, Sn—Ag—In—Bi based solder, Sn—Ag—Cu—Ni based solder, Sn—Cu based solder, In based solder, or the like can be employed.

The insulating layer 21 is provided on the surface 17B of the insulating layer 17 to cover the wiring patterns 19. The insulating layer 21 has opening portions 34 from which a part of the wiring patterns 19 is exposed respectively. As the insulating layer 21, for example, a resin layer may be employed. As the material of the resin layer, for example, an epoxy resin, a polyimide resin, or the like can be employed.

Each of the wiring patterns 22 has a via 36 and a wiring 37 integrally formed with the via 36. The via 36 is provided in the opening portions 34 respectively. One end portion of the via 36 is connected to the wiring pattern 19. Accordingly, the wiring pattern 22 is electrically connected to the chip connecting pad 18 via the wiring pattern 19. The wirings 37 are provided on a surface 21A of the insulating layer 21 (a surface on the opposite side to the surface of the insulating layer 21 that contacts the insulating layer 17). As a material of the wiring pattern 22 constructed as above, for example, Cu can be employed.

The insulating layer 24 is provided on the surface 21A of the insulating layer 21 to cover the wirings 37. The insulating layer 24 has opening portions 39 from which a part of the wiring 37 is exposed respectively. As the insulating layer 24, for example, a resin layer can be employed. As the material of the resin layer, for example, an epoxy resin, a polyimide resin, or the like can be employed.

Each of the wiring patterns 25 has a via 42, and an external connection pad 43 integrally formed with the via 42. The via 42 is provided in the opening portions 39 respectively. One end portion of the via 42 is connected to the wiring 37. Thus, the wiring pattern 25 is electrically connected to the wiring pattern 22. The external connection pads 43 are provided on a surface 24A of the insulating layer 24 (a surface on the opposite side to the surface of the insulating layer 24 that contacts the insulating layer 21). The external connection pads 43 are pads connected to the mounting substrate such as the motherboard, or the like. Each of the external connection pads 43 has a connection surface 43A on which the external connection terminal (not shown) is provided.

The solder resist layer 27 is provided on the surface 24A of the insulating layer 24. The solder resist layer 27 has opening portions 45 from which the connection surface 43A of the external connection pad 43 is exposed respectively.

The stiffener 15 has a through portion 47 to accommodate the semiconductor chip 12. The stiffener 15 is adhered to the surface 17A of the insulating layer 17 in the portion that is positioned on the outside of a chip mounting area A (an area on which the semiconductor chip 12 is flip-chip mounted). The stiffener 15 is formed such that its thermal expansion coefficient is substantially equal to a thermal expansion coefficient of the semiconductor chip 12 (concretely, a thermal expansion coefficient of the semiconductor substrate constituting the semiconductor chip 12 (a thermal expansion coefficient is set to 3 to 4 ppm/° C. when the semiconductor substrate is formed of the silicon substrate)).

In this manner, a thermal expansion coefficient of the stiffener 15 having the through portion 47, in which the semiconductor chip 12 is accommodated, is set substantially equal to a thermal expansion coefficient of the semiconductor chip 12. Therefore, the semiconductor chip 12 and the stiffener 15 functions as a sheet of warp suppressing substrate, so that a warp and a distortion of the multilayer wiring structure 14 can be reduced. As a result, for example, when the wiring substrate 11 is mounted on the mounting substrate such as the motherboard (not shown), reliability of the electric connection between the wiring substrate 11 and the mounting substrate can be improved.

When the semiconductor chip 12 is provided with the silicon substrate (whose thermal expansion coefficient is 3 to 4 ppm/° C.), a value of a thermal expansion coefficient of the stiffener 15 can be set to 1 to 5 ppm/° C., for example. As a material of the stiffener 15, at least one of materials selected from silicon, Carbon Fiber Reinforced Plastic (CFRP), and invar, for example, can be employed. In this case, the material of the stiffener 15 is not restricted to the above materials.

When a thickness of the semiconductor chip 12 is set to 30 to 775 μm and silicon is employed as the material of the stiffener 15, a thickness of the stiffener 15 can be set to 50 to 775 μm, for example.

The semiconductor chip 12 is flip-chip mounted on the chip mounting area A of the multilayer wiring structure 14. The semiconductor chip 12 has a not-shown semiconductor substrate (e.g., a silicon substrate), a semiconductor integrated circuit formed on the semiconductor substrate, and electrode pads 48 electrically connected to the semiconductor integrated circuit. The bump 23 (e.g., Au bump) is provided on the electrode pads 48 respectively. The lower end portion of the bump 23 is secured to the chip connection pads 18 by the solder 20 respectively. Accordingly, the electrode pads 48 are electrically connected to the chip connection pads 18. As the semiconductor chip 12, for example, a semiconductor chip for CPU can be employed.

According to the semiconductor device of the present embodiment, a thermal expansion coefficient of the stiffener 15 having the through portion 47, in which the semiconductor chip 12 is accommodated, is set substantially equal to that of the semiconductor chip 12. Therefore, the semiconductor chip 12 and the stiffener 15 acts as a sheet of warp suppressing substrate, and thus a warp and a distortion of the multilayer wiring structure 14 can be reduced. As a result, for example, when the wiring substrate 11 is mounted on the mounting substrate such as the motherboard (not shown), reliability of the electric connection between the wiring substrate 11 and the mounting substrate can be improved.

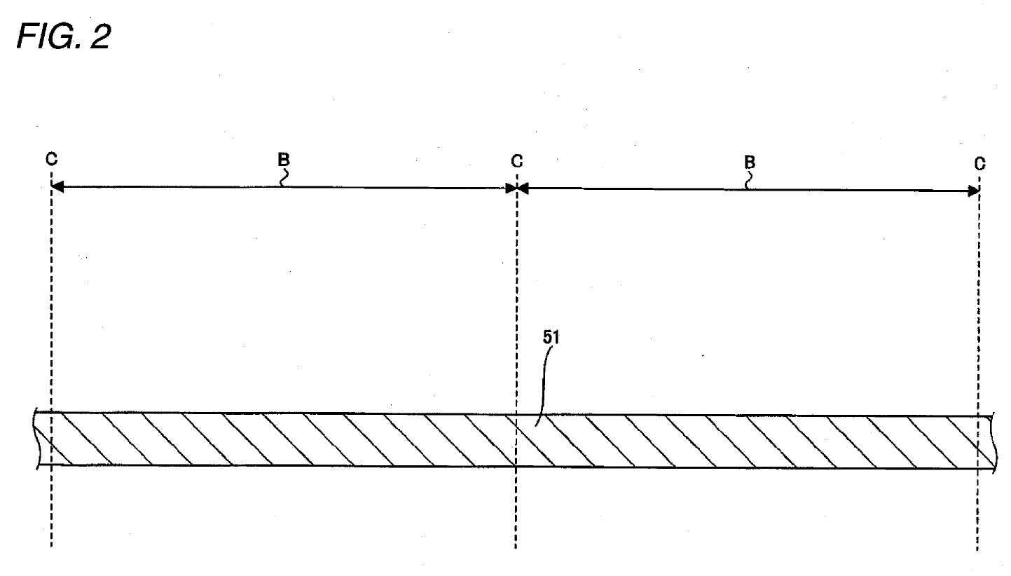

FIG. 2 to FIG. 26 are views showing steps of manufacturing the semiconductor device according to the first exemplary embodiment of the present invention. In FIG. 2 to FIG. 26, the same reference symbols are affixed to the same constituent portions as those of the semiconductor device 10 in the first exemplary embodiment.

By reference to FIG. 2 to FIG. 26, a method of manufacturing the semiconductor device 10 according to the first exemplary embodiment will be described hereunder. At first, in steps shown in FIG. 2, a plate 51 whose thermal expansion coefficient is substantially equal to that of the semiconductor chip 12 is prepared. The plate 51 is a base material of a stiffener base material 53. The plate 51 has a plurality of stiffener forming areas B in which the stiffener 15 is formed respectively. Also, each stiffener forming area B gives an area in which the multilayer wiring structure 14 is formed.

When the semiconductor chip 12 is formed to have the silicon substrate (whose thermal expansion coefficient is 3 to 4 ppm/° C.), a thermal expansion coefficient of the plate 51 can be set to 1 to 5 ppm/° C., for example. As a material of the plate 51, for example, silicon, Carbon Fiber Reinforced Plastic (CFRP), invar, or the like can be employed. When the silicon is used as the material of the plate 51, a thickness of the plate 51 can be set to 200 mm, for example.

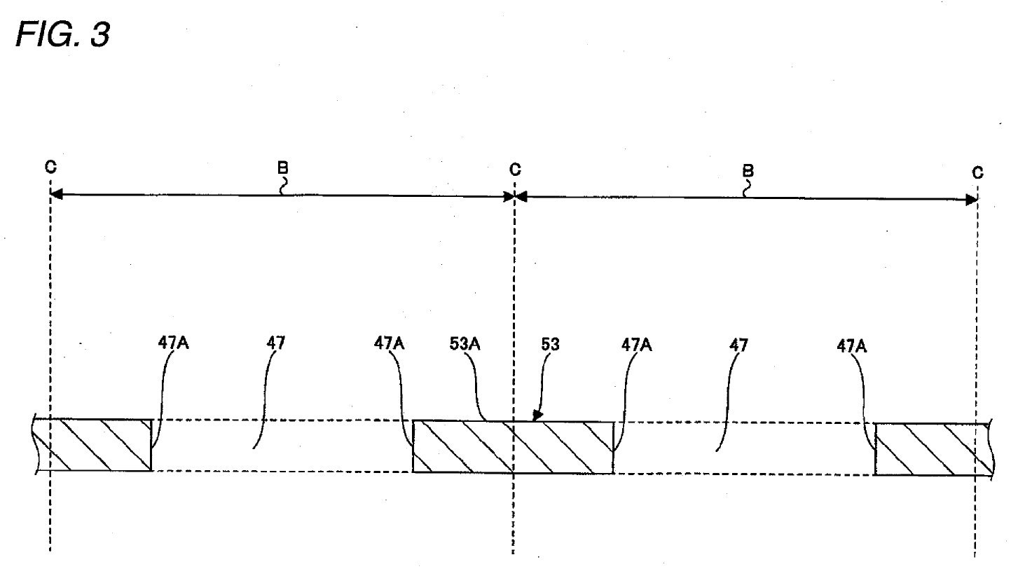

Then, in steps shown in FIG. 3, the stiffener base material 53 is formed by forming the through portion 47 in the portion of the plate 51 corresponding to the center of the stiffener forming area B (steps shown in FIG. 2 and FIG. 3 correspond to a “stiffener base material forming step”). An angle between a side surface 47A of the through portion 47 and an upper surface 53A of the stiffener base material 53 is set to almost 90 degree. The through portion 47 is formed by applying the machining (e.g., the punching) to the plate 51, for example.

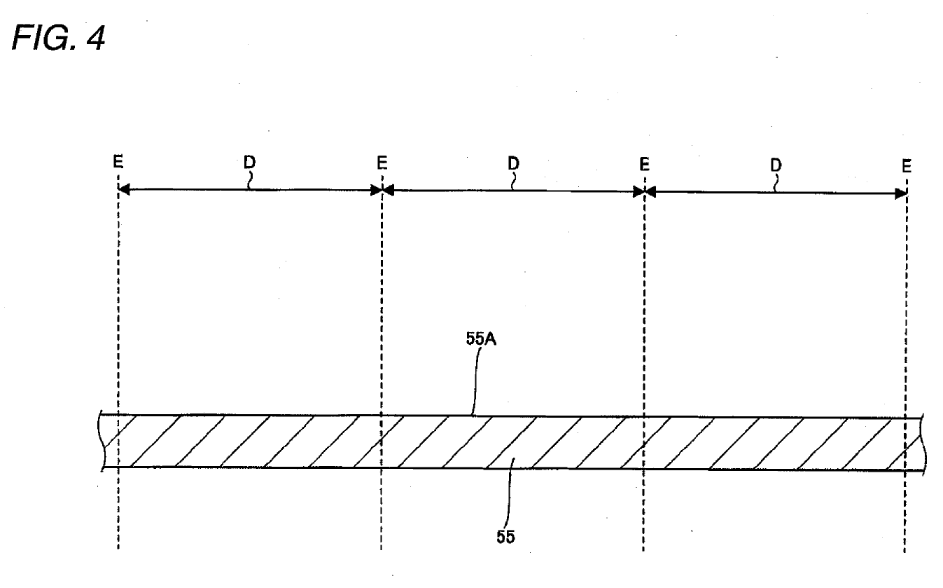

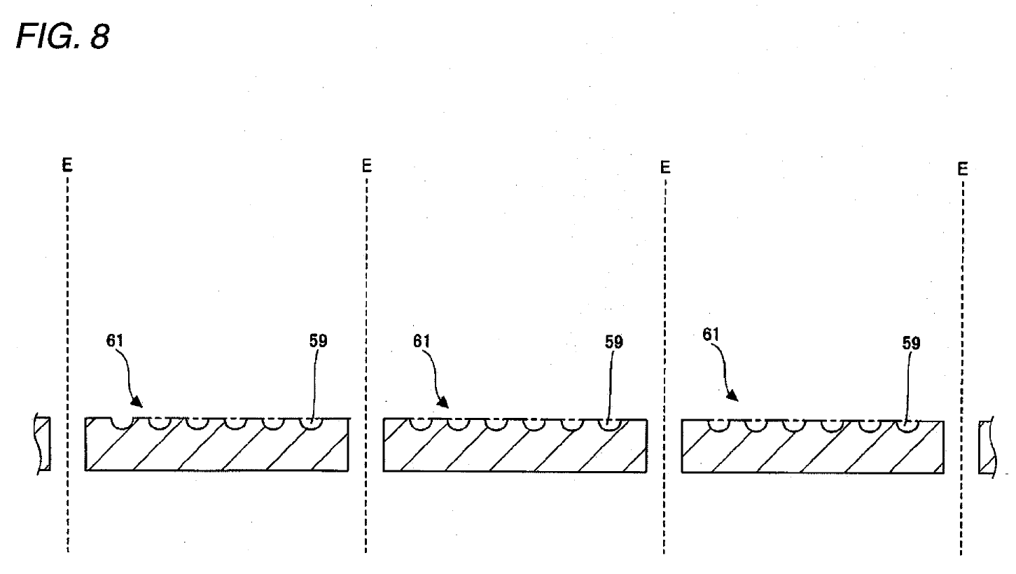

Then, in steps shown in FIG. 4, a substrate 55 whose thermal expansion coefficient is substantially equal to that of the semiconductor chip 12 is prepared. The substrate 55 is a member in which a plurality of convex portions 61 (see FIG. 8) of a support 71 are inserted into the through portion 47 of the stiffener base material 53, as described later. The substrate 55 has a plurality of convex portion forming areas D on which the convex portions 61 are formed. A thermal expansion coefficient of the substrate 55 is set substantially equal to that of the semiconductor chip 12. As a material of the substrate 55, for example, silicon, glass, Carbon Fiber Reinforced Plastic (CFRP), invar can be employed. When the silicon is employed as the material of the substrate 55, a thickness of the substrate 55 can be set to 500 μm, for example.

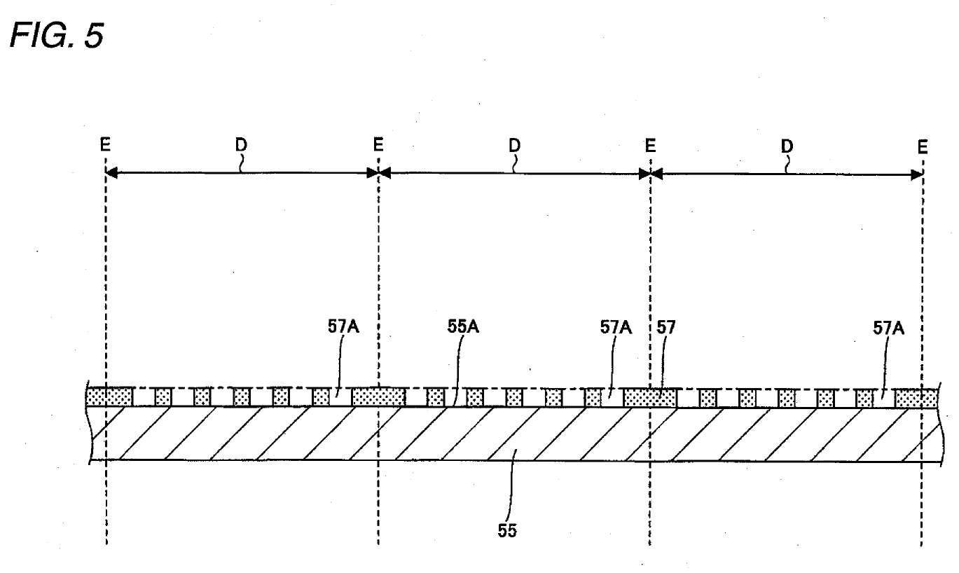

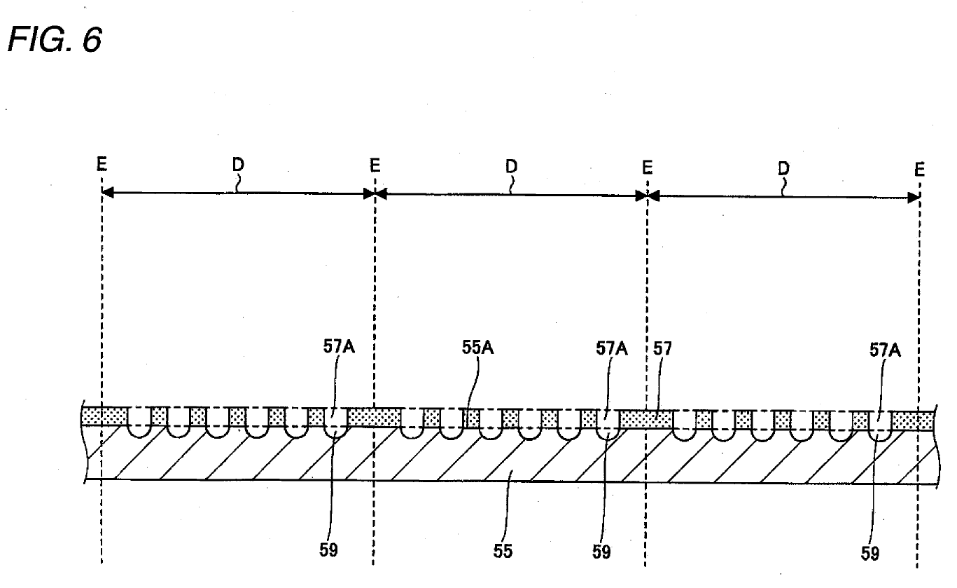

Then, in steps shown in FIG. 5, a resist film 57 in which opening portions 57A are formed is formed on an upper surface 55A of the substrate 55. Then, in steps shown in FIG. 6, a plurality of concave portions 59 are formed in the upper surface 55A side of the substrate 55 by the etching using the resist film 57 as a mask. The concave portions 59 are areas on which the solder 20 is provided respectively. As the above etching, for example, the wet etching or the dry etching can be employed. As the dry etching, the etching using ICP plasma, for example, can be used. As the etching gas in this case, a SF₆ gas, for example, can be employed.

An alignment pitch of the concave portions 59 is set substantially equal to that of the electrode pads provided to the semiconductor chip 12. The alignment pitch of the concave portions 59 can be set to 1 μm to 50 μm, for example. Also, a depth of the concave portion 59 can be set to 1 μm to 20 μm, for example.

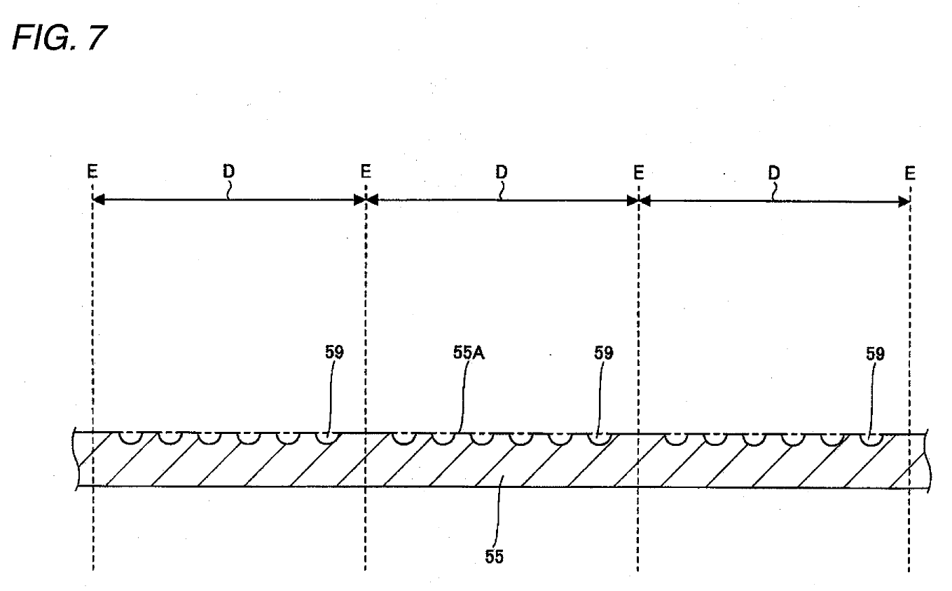

Then, in steps shown in FIG. 7, the resist film 57 shown in FIG. 6 is removed. Then, in steps shown in FIG. 8, the structure shown in FIG. 7 is cut along a cutting position E respectively. Accordingly, a plurality of the convex portions 61 of the support 71 described later are formed.

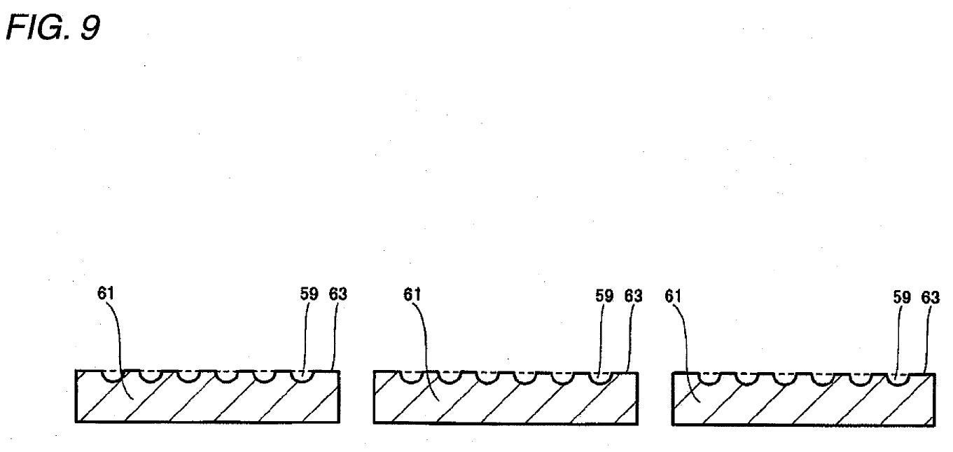

Then, in steps shown in FIG. 9, a metal film 63 is formed to cover the whole surface of the convex portion 61 (containing the surface of the convex portion 61 in the portion constituting the concave portions 59). The metal film 63 is a film acting as a power feeding layer when the solder 20 is formed on the concave portions 59 by the electroplating process respectively. The metal film 63 can be formed by the sputter method, for example. As the metal film 63, for example, a Ti/Cu layered film formed by layering sequentially a Ti film (e.g., thickness 0.1 μm) and a Cu film (e.g., thickness 0.1 μm) on the whole surface of the convex portion 61 can be employed.

Also, instead of the Ti/Cu layered film, for example, a metal film that is hard to be alloyed with the solder 20 (concretely, for example, Al film, Cr film, Pt film, or the like) may be employed as the metal film 63.

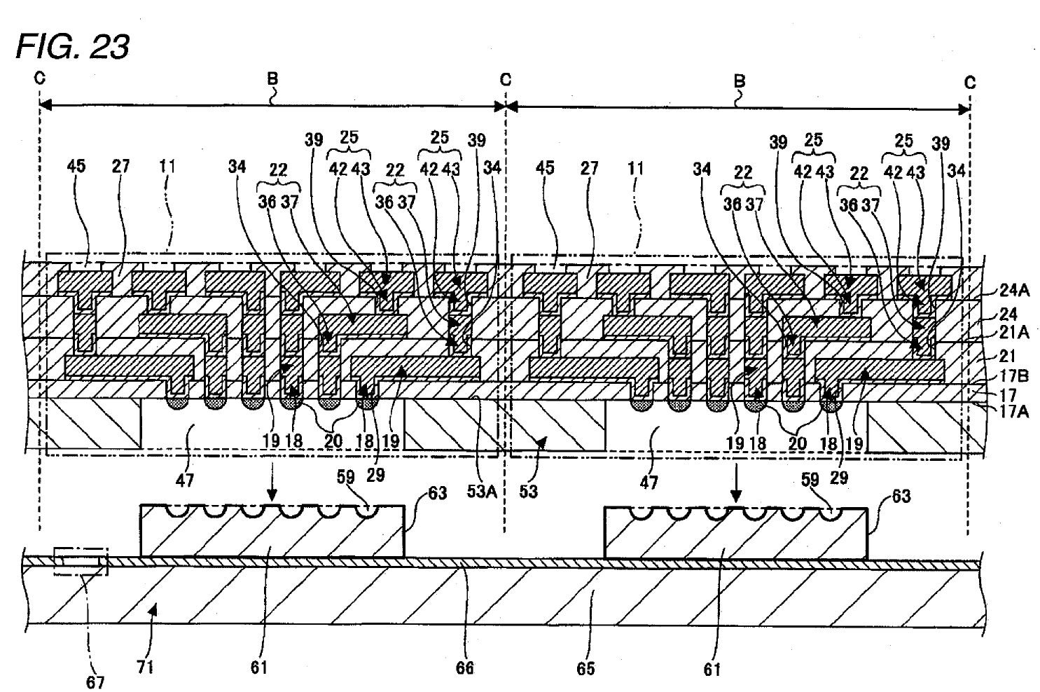

In this way, as the metal film 63 serving as the power feeding layer when the solder 20 is formed on the concave portions 59 respectively, the metal film that is hard to be alloyed with the solder 20 (concretely, for example, Al film, Cr film, Pt film, or the like) is employed. Therefore, in steps shown in FIG. 23 described later (support removing step), the convex portions 61 on which the metal film 63 is formed can be easily removed when the convex portions 61 on which the metal film 63 is formed are removed from the multilayer wiring structure 14 on which the solders 20 are formed. When Al film is employed as the metal film 63, a thickness of the metal film 63 can be set to 0.5 μm, for example.

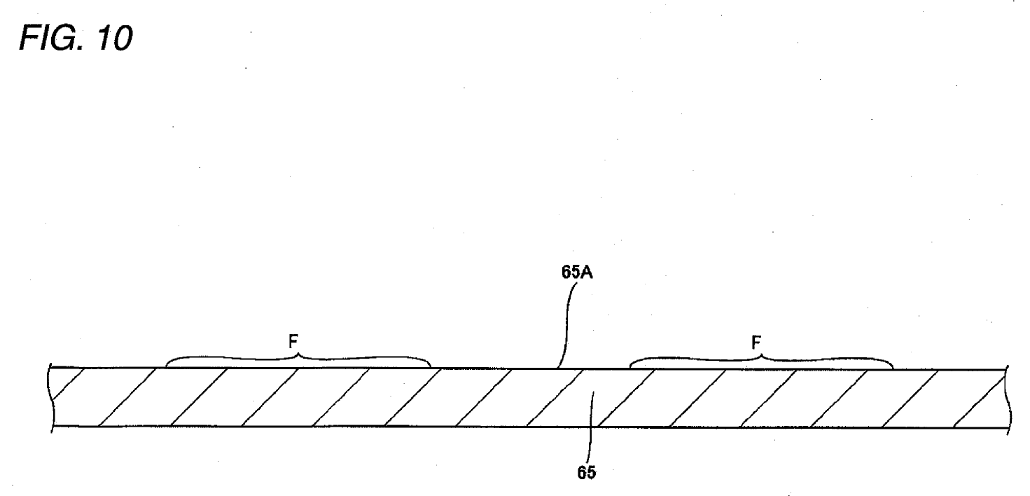

Then, in steps shown in FIG. 10, a supporting substrate 65 is prepared. A plurality of convex portion providing areas F, in which the convex portions 61 formed with the metal film 63 are provided respectively, are provided on the supporting substrate 65. Also, a thermal expansion coefficient of the supporting substrate 65 is set substantially equal to that of the semiconductor chip 12.

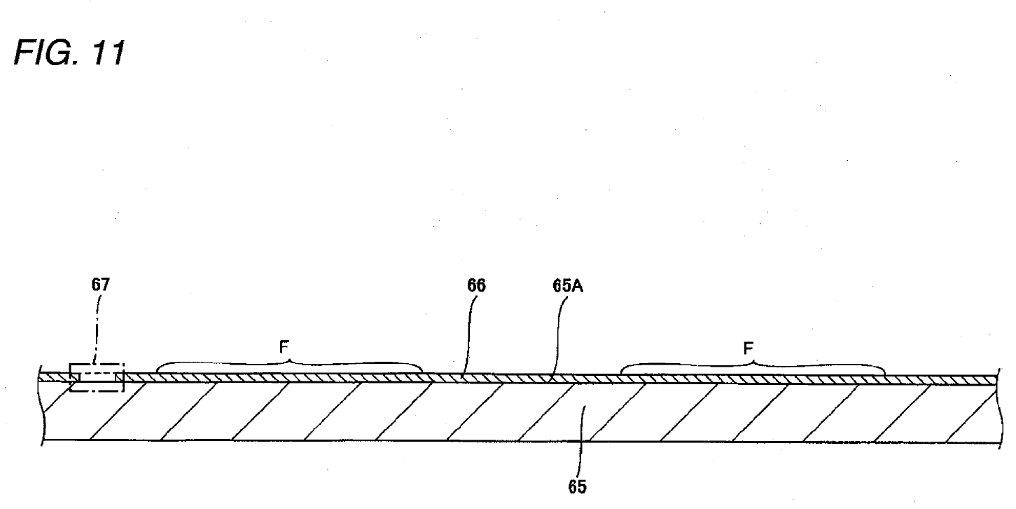

Then, in steps shown in FIG. 11, a metal film 66 is formed to cover an upper surface 65A of the supporting substrate 65, and then a part of portions of the metal film 66 except the convex portion providing areas F is removed by the etching. Thus, alignment marks 67 are formed. The metal film 66 is used to feed a power to the metal film 63 when the solder 20 is formed by the electroplating process. As the metal film 66, for example, a Ti/Cu layered film formed by layering sequentially a Ti film (e.g., thickness 0.1 μm) and a Cu film (e.g., thickness 0.1 μm) on the upper surface 65A of the supporting substrate 65 can be employed. The alignment marks 67 are used when the convex portions 61 each formed with the metal film 63 are put on given areas (the convex portion providing areas F) of the supporting substrate 65 respectively.

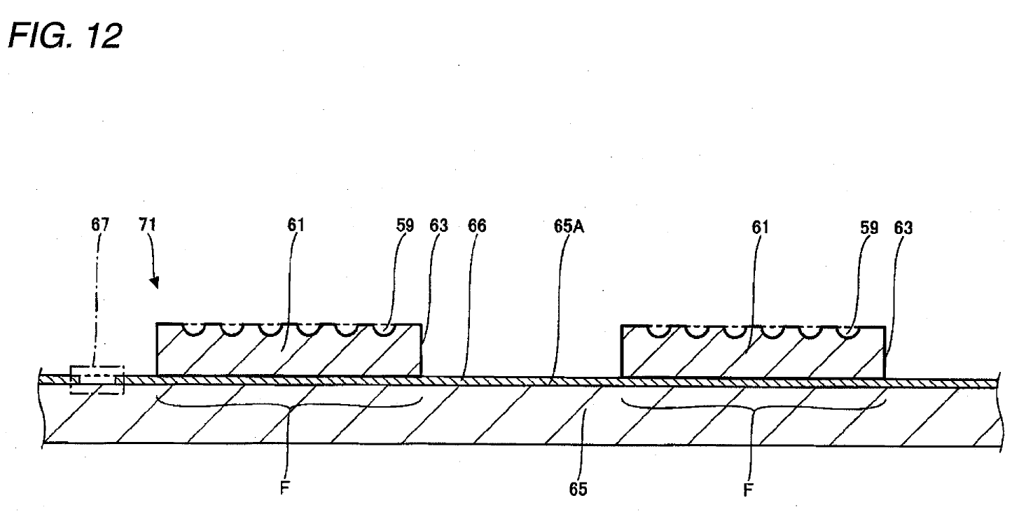

Then, in steps shown in FIG. 12, the convex portions 61 each formed with the metal film 63 are adhered onto portions of the metal film 66 corresponding to the convex portion providing areas F. Then, the metal film 63 formed on the convex portions 61 respectively is electrically connected to the metal film 66 formed on the supporting substrate 65. Thus, the support 71 is formed which includes a plurality of convex portions 61 each formed with the metal film 63 and the supporting substrate 65 on which the metal film 66 is formed (steps shown in FIG. 4 to FIG. 12 correspond to a “support forming step”). In adhering the metal film 63 to the metal film 66, for example, the conductive adhesive (e.g., Ag paste, carbon tape, or the like) can be employed.

Also, in steps shown in FIG. 12, the convex portions 61 each formed with the metal film 63 are bonded onto the portions of the metal film 66 corresponding to the convex portion providing areas F, by using the alignment marks 67 formed on the metal film 66. Accordingly, the convex portions 61 each formed with the metal film 63 can be adhered to the convex portion providing areas F on the supporting substrate 65 with good positional precision.

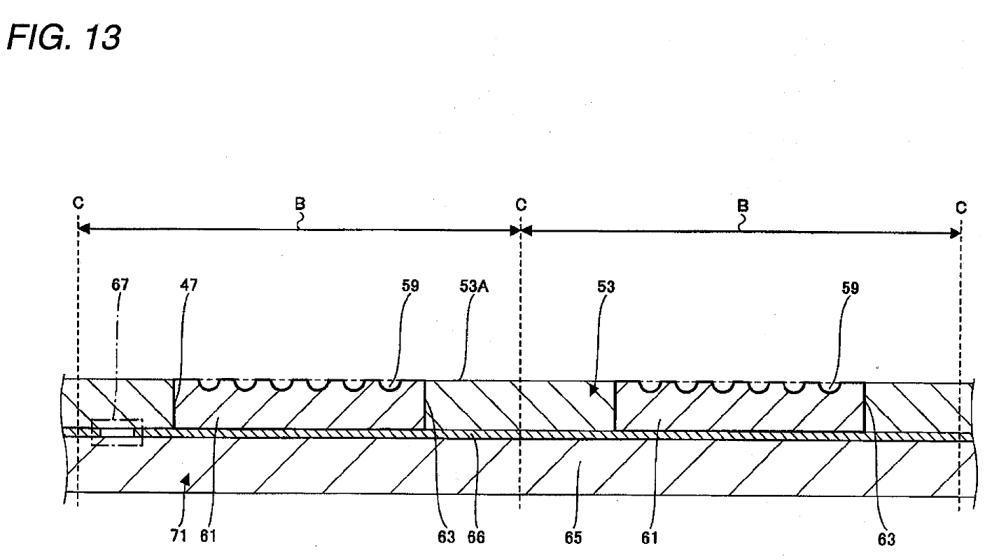

Then, in steps shown in FIG. 13, the stiffener base material 53 and the support 71 are tentatively adhered mutually by inserting the convex portions 61 each formed with the metal film 63 into the through portion 47 provided in the stiffener base material (“tentatively adhering step”). In tentatively adhering the stiffener base material 53 to the support 71, for example, the double faced tape of thermally peelable type can be employed.

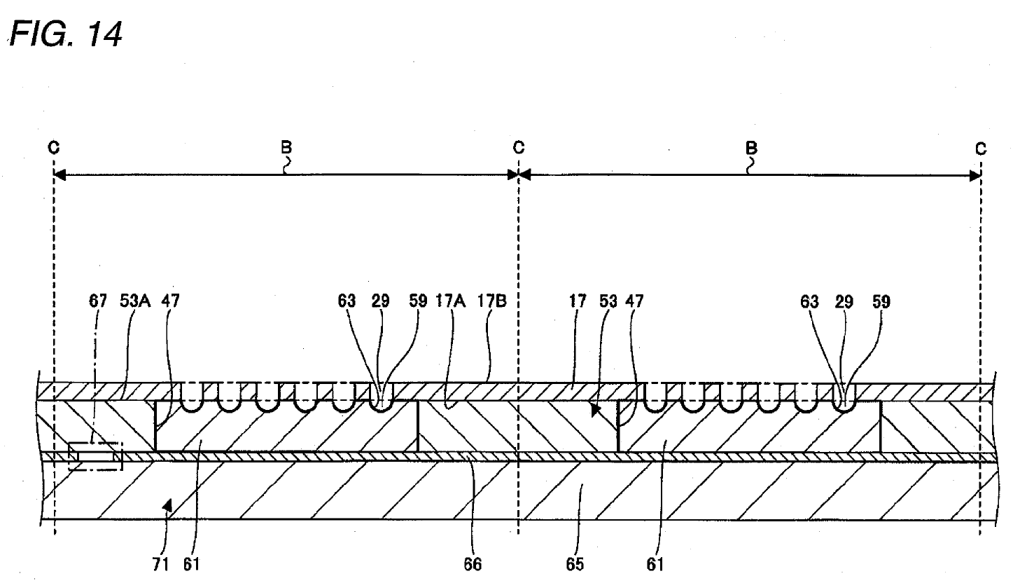

Then, in steps shown in FIG. 14, the insulating layer 17 having a plurality of through holes 29 is formed on the upper surface 53A of the stiffener base material 53 and the metal film 63 formed on the convex portions 61 on the side on which the concave portions 59 are provided. As the insulating layer 17, for example, a resin layer can be employed. Also, as a material of the resin layer, for example, an epoxy resin, a polyimide resin, and the like can be employed. When the resin layer is employed as the insulating layer 17, a thickness of the insulating layer 17 can be set to 5 μm to 30 μm, for example. The through holes 29 are formed to expose portions of the metal film 63 formed on the concave portions 59. The through holes 29 can be formed by the laser beam machining, for example.

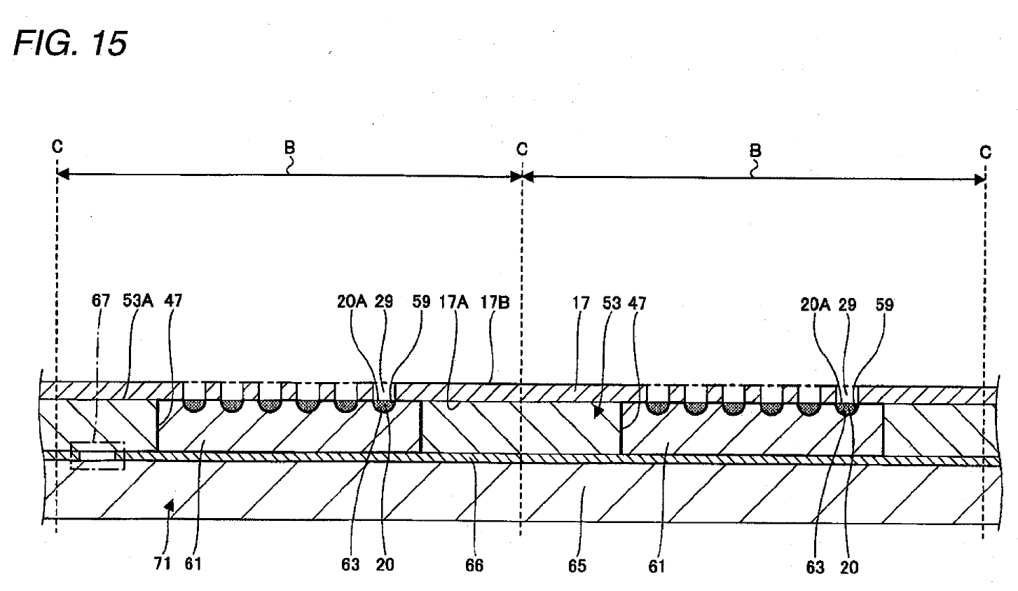

Then, in steps shown in FIG. 15, the solder 20 is formed by the electroplating process using the metal films 63, 66 as a power feeding layer to fill the concave portions 59 on which the metal film 63 is formed. As the solder 20, for example, Sn—Ag—Cu based solder, Sn—Zn—Bi based solder, Sn—Ag—In—Bi based solder, Sn—Ag—Cu—Ni based solder, Sn—Cu based solder, In based solder, or the like can be employed.

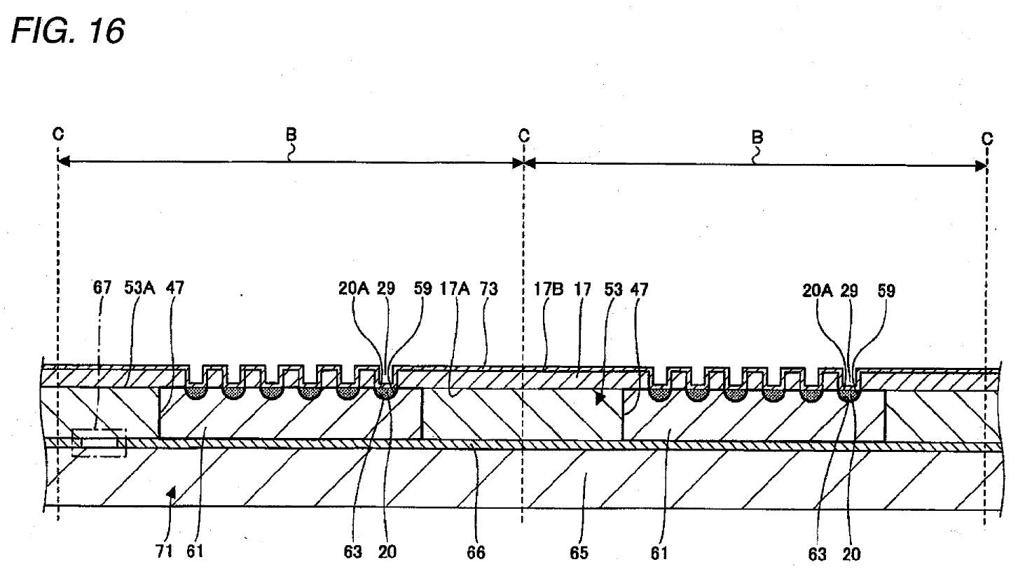

Then, in steps shown in FIG. 16, a seed layer 73 is formed to cover upper surfaces 20A of the solders 20, surfaces of the portions of the insulating layer 17 corresponding to side surfaces of the through holes 29, and the surface 17B of the insulating layer 17. Concretely, for example, the palladium process is subjected to surfaces of the portions of the insulating layer 17 corresponding to the side surfaces of the trough holes 29 and the surface 17B of the insulating layer 17, and then the plated film is deposited by the electroless plating process, thereby forming the seed layer 73. As the seed layer 73, for example, a Cu layer can be employed. When the Cu layer is employed as the seed layer 73, a thickness of the seed layer 73 can be set to 0.1 μm, for example.

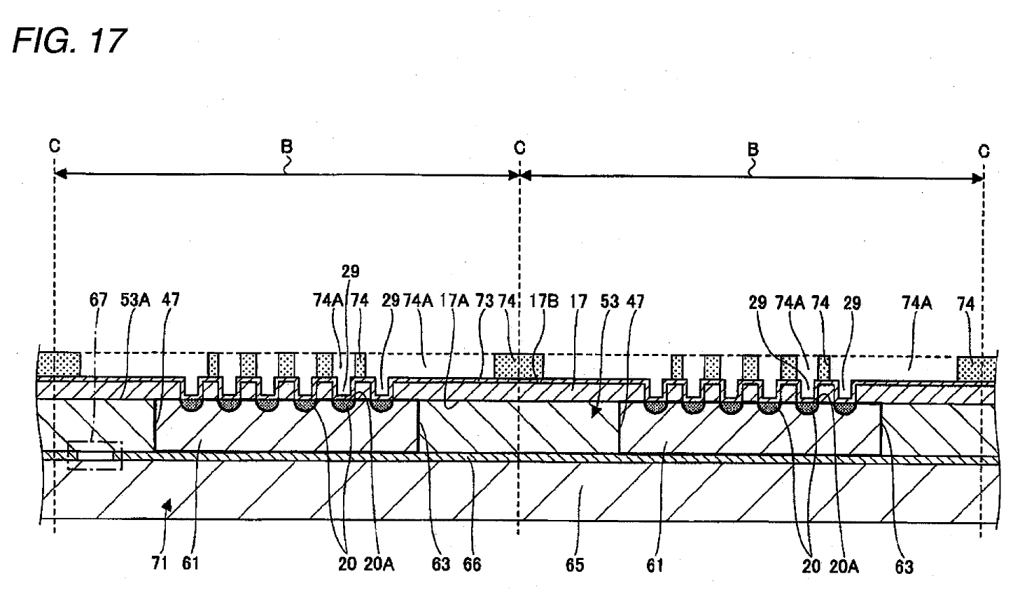

Then, in steps shown in FIG. 17, a resist film 74 having opening portions 74A therein is formed on the seed layer 73. The opening portions 74A are formed to expose upper surfaces of portions of the seed layer 73 corresponding to the forming areas of the chip connection pads 18 and the wiring patterns 19.

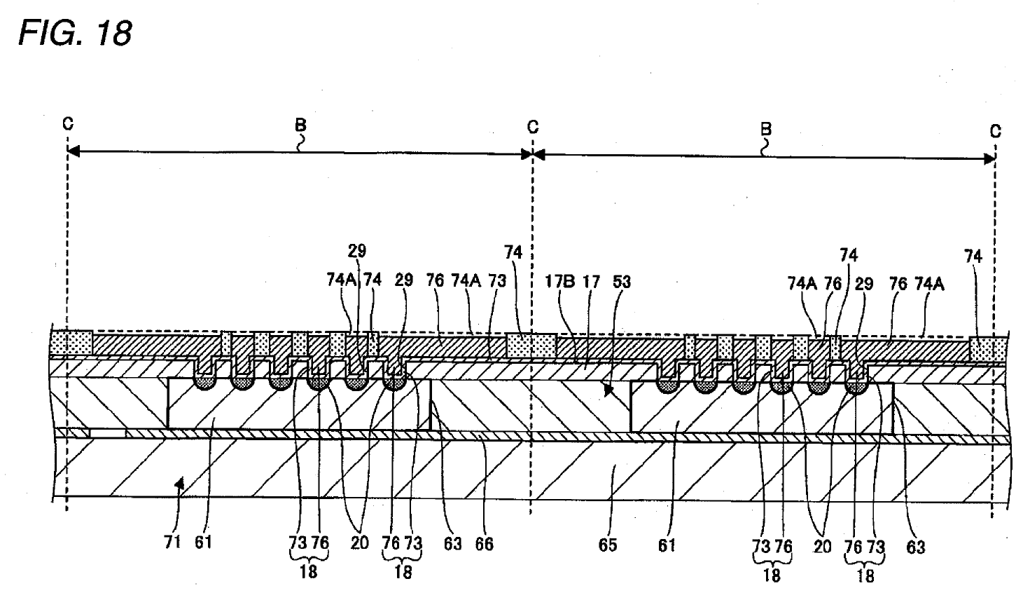

Then, in steps shown in FIG. 18, a plated film 76 is deposited on portions of the seed layer 73 exposed from the opening portions 74A respectively, by the electroplating process using the seed layer 73 as a power feeding layer. Accordingly, the chip connection pad 18 consisting of the seed layer 73 and the plated film 76 is formed in the through holes 29 in the insulating layer 17 respectively. As the plated film 76, for example, a Cu plated film can be employed.

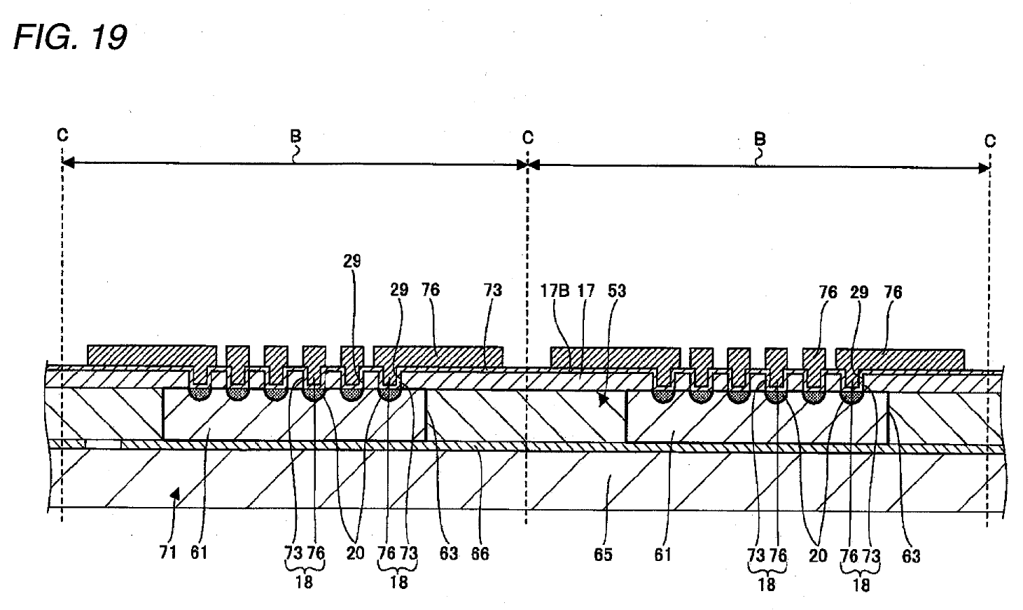

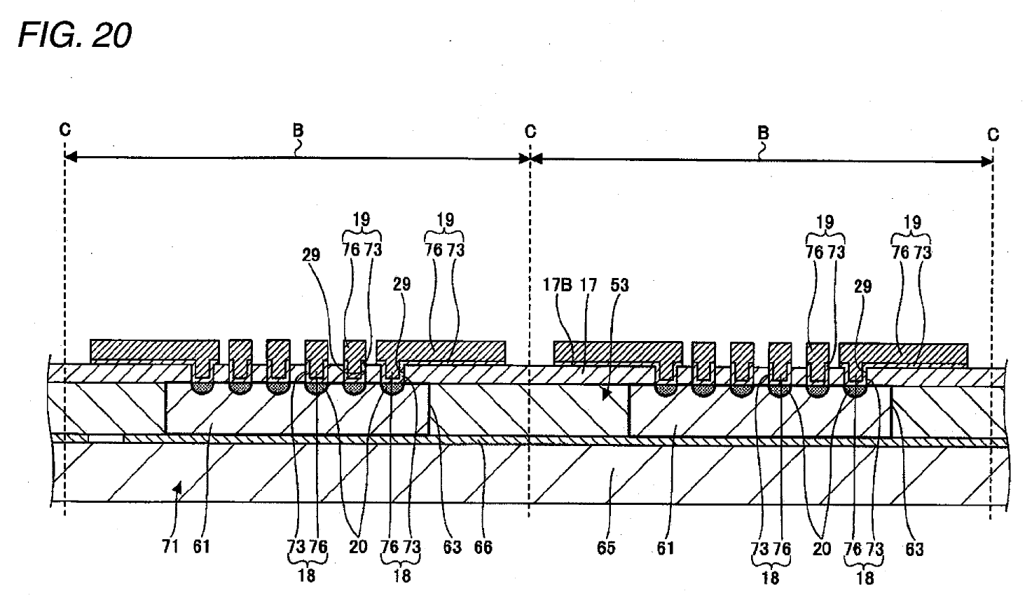

Then, in steps shown in FIG. 19, the resist film 74 provided to the structure shown in FIG. 18 is removed. Then, in steps shown in FIG. 20, unnecessary portions of the seed layer 73 provided to the structure shown in FIG. 19 (concretely, portions of the seed layer 73 not covered with the plated film 76) are removed. Concretely, for example, the unnecessary portions of the seed layer 73 are removed by the wet etching. Accordingly, the wiring patterns 19 each consisting of the seed layer 73 and the plated film 76 are formed on the surface 17B of the insulating layer 17.

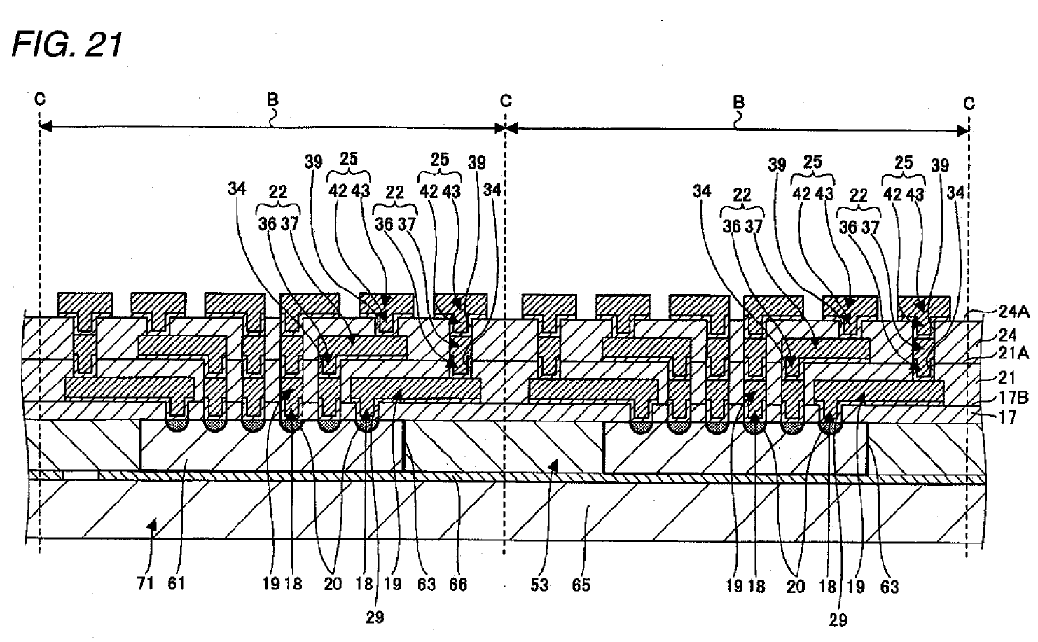

Then, in steps shown in FIG. 21, the insulating layer 21 having the opening portions 34, the wiring patterns 22, the insulating layer 24 having the opening portions 39, and the wiring patterns 25 are formed sequentially by the approaches similar to steps shown in FIG. 14 to FIG. 20 described above. As the insulating layers 21, 24, for example, a resin layer can be employed. Also, as a material of the resin layer, for example, an epoxy resin or a polyimide resin can be employed. When the resin layer is used as the insulating layers 21 and 24, a thickness of the insulating layer 21 can be set to 5 μm to 30 μm, for example, and a thickness of the insulating layer 24 can be set to 5 μm to 30 μm, for example. The opening portions 34 and 39 can be formed by the laser beam machining, for example.

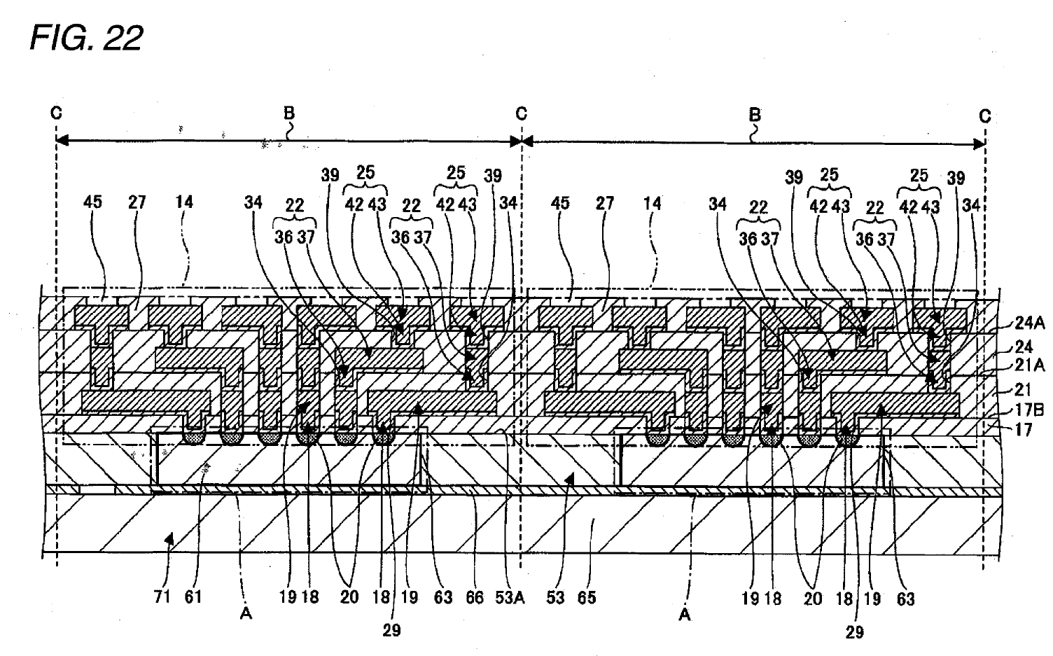

Then, in steps shown in FIG. 22, the solder resist layer 27 having the opening portions 45 is formed on the surface 24A of the insulating layer 24. Thus, the multilayer wiring structure 14 is formed on the portion of the upper surface 53A of the stiffener base material 53, which corresponds to the stiffener forming area B, and the convex portion 61 (steps shown in FIG. 14 to FIG. 22 correspond to a “multilayer wiring structure forming step”). In this phase, a plurality of multilayer wiring structures 14 are still integrally formed with each other, and are not diced into individual pieces yet.

In this fashion, the multilayer wiring structure 14 is formed on the metal film 63 formed on the upper surface of the convex portion 61 and the upper surface 53A of the stiffener base material 53 positioned on the upper surface side of the convex portion 61 in such a situation that the convex portion 61 whose thermal expansion coefficient is substantially equal to the semiconductor chip 12 is inserted into the through portion 47 of the stiffener base material 53 that accommodates the semiconductor chip 12. Thus, the convex portion 61 whose thermal expansion coefficient is substantially equal to the semiconductor chip 12 functions as a dummy of the semiconductor chip 12. As a result, the multilayer wiring structure 14 can be formed in a state similar to the state that the semiconductor chip 12 is mounted in advance. Accordingly, displacement of the chip connection pads 18 from the electrode pads 48 provided on the semiconductor chip 12 can be eliminated. As a result, reliability of the electric connection between the semiconductor chip 12 that is flip-chip connected to the chip connection pads 18 and the multilayer wiring structure 14 can be improved.

Then, in steps shown in FIG. 23, the support 71 is removed from the stiffener base material 53 (support removing step). Concretely, for example, when the double faced tape of thermally peelable type is employed to adhere the stiffener base material 53 to the support 71, the support 71 is removed from the stiffener base material 53 by heating the structure shown in FIG. 22. Accordingly, a plurality of wiring substrates 11 that are not diced into individual pieces are formed.

In this way, the support 71 is removed from the stiffener base material 53 on which a plurality of multilayer wiring structures 14 are formed. Therefore, a warp and a distortion of the multilayer wiring structure 14 can be reduced by the stiffener base material 53 after the support is removed from the multilayer wiring structure. As a result, when the semiconductor chip 12 is flip-chip mounted on the chip connection pads 18 of the multilayer wiring structure 14, reliability of the electric connection between the semiconductor chip 12 and the multilayer wiring structure 14 can be improved.

Also, a warp and a distortion of the multilayer wiring structure 14 can be reduced in this way. Therefore, for example, when the semiconductor device 10 is mounted on the mounting substrate such as the motherboard, or the like (not shown), reliability of the electric connection between the semiconductor device 10 and the mounting substrate can be improved.

Further, the support 71 removed from the stiffener base material 53 can be reused in manufacturing a plurality of other wiring substrates 11. Therefore, a manufacturing cost of the wiring substrate 11 can be reduced in contrast to the conventional approach by which the multilayer wiring structure 14 is formed by using the Cu plate as the support (in this case, the Cu plate cannot be used again since this Cu plate is removed by etching).

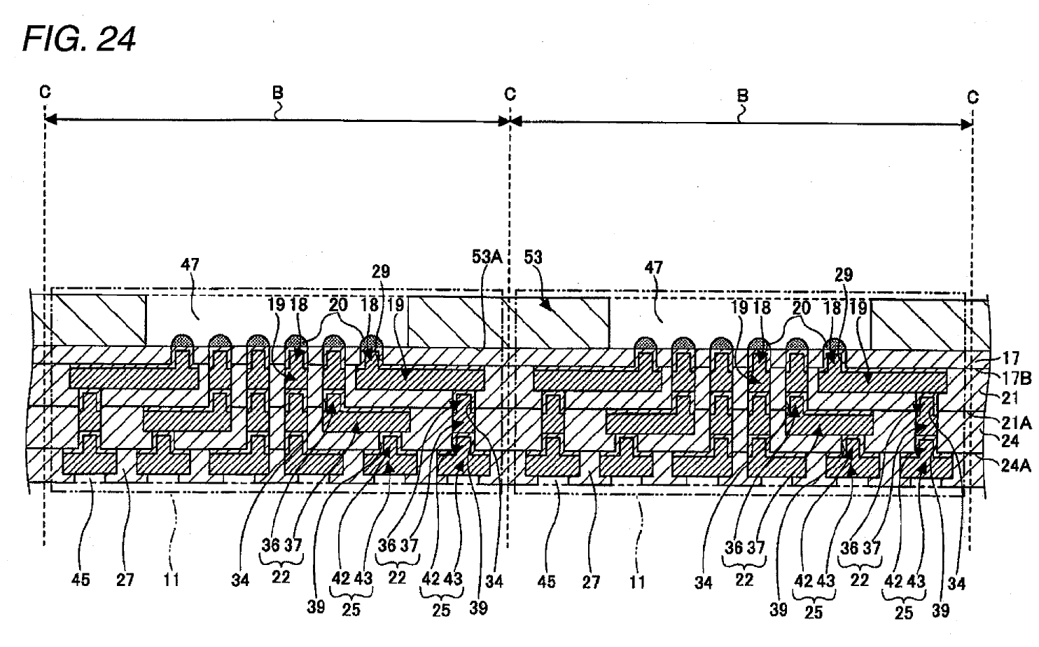

Then, in steps shown in FIG. 24, the structure that includes the stiffener base material 53 shown in FIG. 23 and a plurality of multilayer wiring structures 14 is turned upside down.

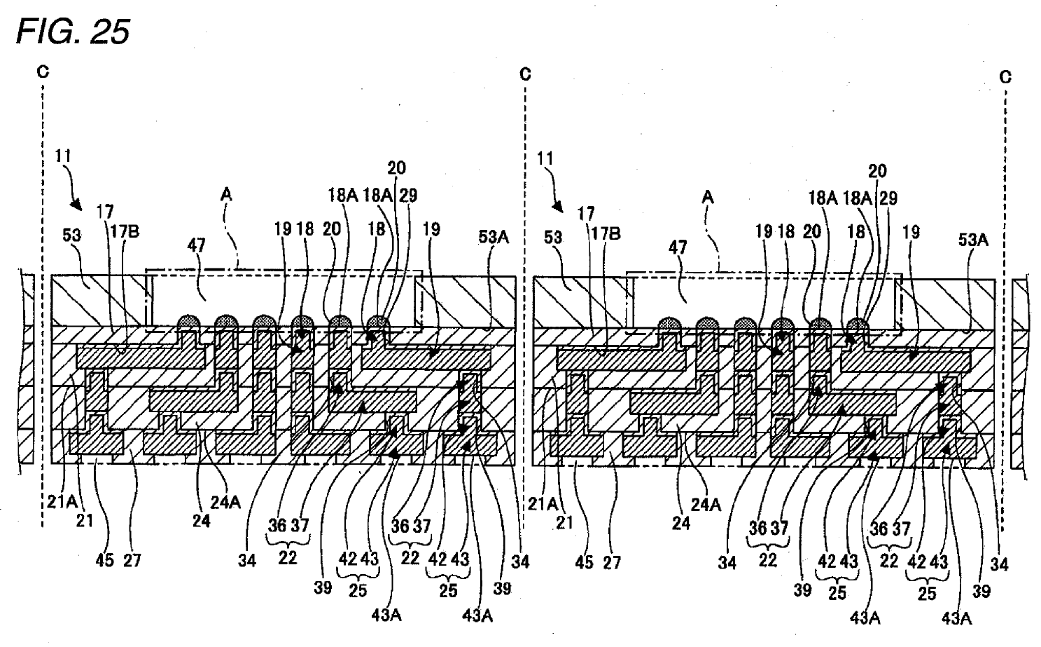

Then, in steps shown in FIG. 25, the multilayer wiring structures 14 and the stiffener 15 are diced into individual pieces by cutting the structure shown in FIG. 24 along a cutting position C respectively (cutting step). Accordingly, a plurality of wiring substrates 11 are manufactured.

In this manner, a plurality of multilayer wiring structures 14 that are not diced into individual pieces yet are formed on the stiffener base material 53 as the base material of a plurality of the stiffeners 15, and then the plurality of multilayer wiring structures 14 and the stiffener base material 53, which are not diced into individual pieces, are cut along the cutting position C respectively. As a result the plurality of wiring substrates 11 can be manufactured at a time.

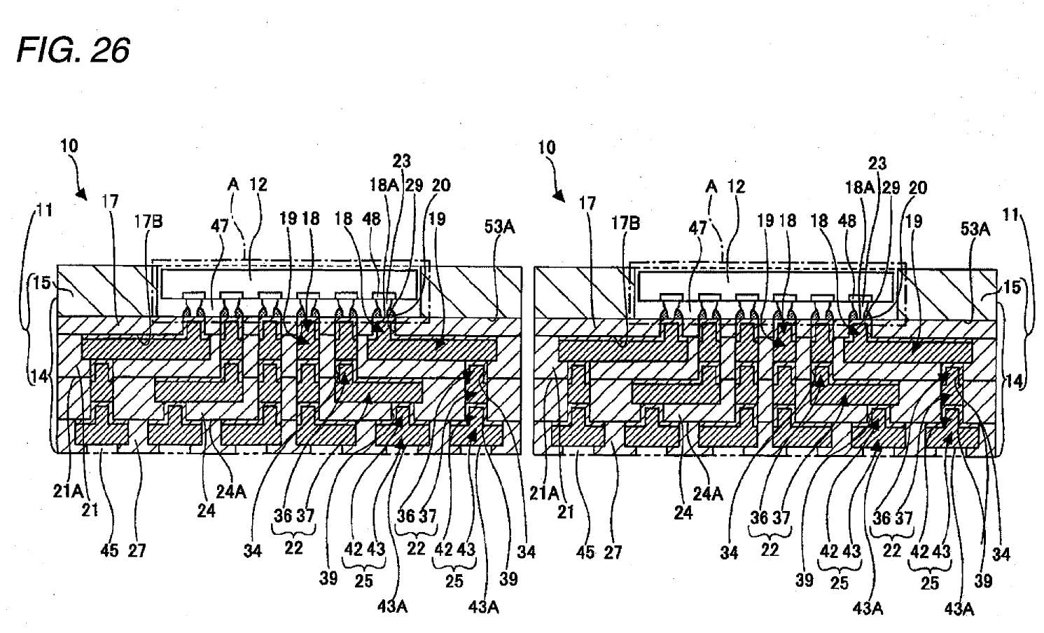

Then, in steps shown in FIG. 26, the semiconductor chip 12 on the electrode pads 48 each connected to the bump 23 is flip-chip mounted onto the chip connection pads 18 of the multilayer wiring structure 14. Accordingly, the semiconductor device 10 of the first exemplary embodiment is manufactured.

According to the method of manufacturing the semiconductor device according to the present embodiment, the multilayer wiring structure 14 is formed on the metal film 63 formed on the upper surface of the convex portion 61 and the upper surface 53A of the stiffener base material 53 positioned on the upper surface side of the convex portion 61 in such a situation that the convex portion 61 whose thermal expansion coefficient is substantially equal to the semiconductor chip 12 is inserted into the through portion 47 of the stiffener base material 53 that accommodates the semiconductor chip 12. The convex portion 61 whose thermal expansion coefficient is substantially equal to the semiconductor chip 12 serves as a dummy of the semiconductor chip 12. As a result, the multilayer wiring structure 14 can be formed in a state similar to the state that the semiconductor chip 12 is mounted in advance. Accordingly, displacement of the chip connection pads 18 from the electrode pads 48 provided on the semiconductor chip 12 can be eliminated. As a result, reliability of the electric connection between the semiconductor chip 12 that is flip-chip connected to the chip connection pads 18 and the multilayer wiring structure 14 can be improved.

Also, the support 71 is removed from the stiffener base material 53 on which a plurality of multilayer wiring structures 14 are formed. Therefore, a warp and a distortion of the multilayer wiring structure 14 can be reduced by the stiffener base material 53 after the support is removed from the multilayer wiring structure. As a result, when the semiconductor chip 12 is flip-chip mounted on the chip connection pads 18 of the multilayer wiring structure 14, reliability of the electric connection between the semiconductor chip 12 and the multilayer wiring structure 14 can be improved.

Also, a warp and a distortion of the multilayer wiring structure 14 can be reduced in this way. Therefore, for example, when the semiconductor device 10 is mounted on the mounting substrate such as the motherboard (not shown), reliability of the electric connection between the semiconductor device 10 and the mounting substrate can be improved.

Further, the support 71 removed from the stiffener base material 53 can be reused in manufacturing a plurality of other wiring substrates 11. Therefore, a manufacturing cost of the wiring substrate 11 can be reduced in contrast to the conventional approach by which the multilayer wiring structure 14 is formed by using the Cu plate as the support (in this case, the Cu plate cannot be used again since this Cu plate is removed by etching).

In this case, in the present embodiment, the case where the solder 20 is formed by the electroplating process is explained by way of example. But the solder 20 may be formed by the ink jet method. In this case, the process in steps shown in FIG. 9 is not needed, and therefore a manufacturing cost of the semiconductor device 10 can be further lowered.

Also, in the present embodiment, the case where the semiconductor device 10 is manufactured by using the support 71 in which the convex portions 61 and the supporting substrate 65 are formed as the separate body is explained by way of example. But the semiconductor device 10 may be manufactured by using the support in which the convex portions 61 and the supporting substrate 65 are integrally formed with each other. In this case, the metal film (the metal film acting as the power feeding layer when the solder 20 is formed by the electroplating process) can be formed at a time on the surface of the support.

Also, in the present embodiment, the case where the solder 20 is formed by the electroplating process to fill the concave portions 59 in steps shown in FIG. 15 is explained by way of example. In this case, instead of the solder 20, the bumps may be formed by filling the concave portions 59 with the metal other than the solder by means of the electroplating process. Concretely, a gold layer and a nickel layer are formed sequentially on inner walls of the concave portions 59 by the electroplating process, then a copper film serving as a bump main body is formed by the electroplating process to fill the concave portions 59, and then the support is removed after the multilayer wiring structure is formed. Thus, the bumps are formed such that a surface of the bump main body made of the copper film is covered with the nickel layer (the nickel layer is covered with the gold layer) respectively. When the semiconductor chip 12 is mounted on the wiring substrate having such bumps, the semiconductor chip 12 is flip-chip connected to the wiring substrate after the solder paste is formed on the bump surfaces in advance.

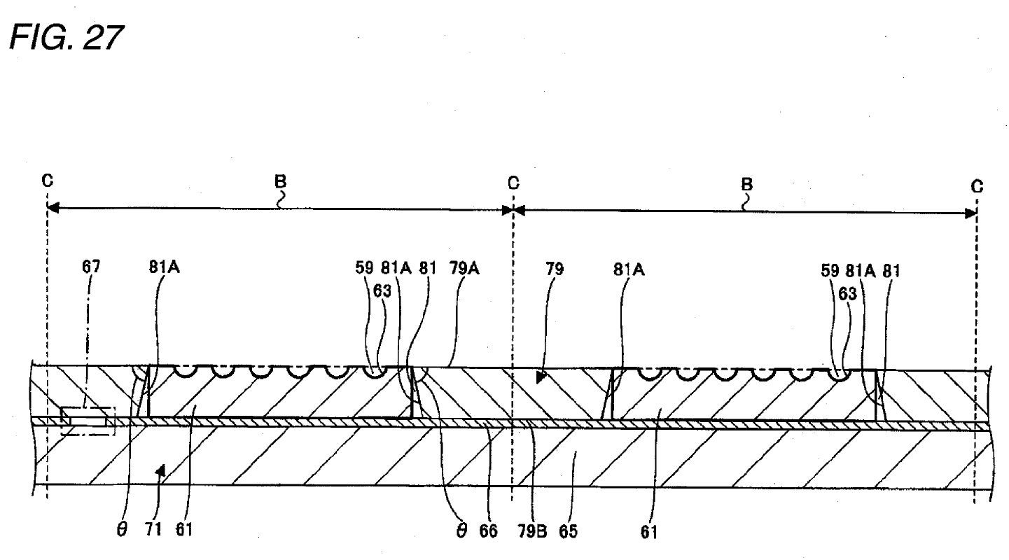

Also, in the present embodiment, the case where the semiconductor device 10 is manufactured by using the stiffener base material 53 constructed such that an angle between the upper surface 53A of the stiffener base material 53 and the side surface 47A of the through portion 47 is set to almost 90 degree is explained by way of example. But the semiconductor device 10 may be manufactured by using a stiffener base material 79 shown in FIG. 27 instead of the stiffener base material 53.

FIG. 27 is a view explaining another stiffener base material.

By reference to FIG. 27, the stiffener base material 79 has through portions 81 each of which accommodates the convex portion 61 formed with the metal film 63. A sectional shape of the through portion 81 is broadened gradually from an upper surface 79A of the stiffener base material 79 (the side on which the multilayer wiring structure 14 is formed) toward the bottom (a lower surface 79B (the side through which the support 71 is inserted)).

In this manner, a sectional shape of the through portion 81 which accommodates the convex portion 61 formed with the metal film 63 is broadened gradually from the upper surface 79A of the stiffener base material 79 (the side on which the multilayer wiring structure 14 is formed) toward the lower surface 79B of the stiffener base material 79. Therefore, the support 71 can be easily removed from the stiffener base material 79 in the support removing step.

An angle θ between the upper surface 79A of the stiffener base material 79 and a side surface 81A of the through portion 81 can be set to 1° to 30°, for example. The stiffener base material 79 is formed of the material similar to the stiffener 15 having a thermal expansion coefficient that is substantially equal to a thermal expansion coefficient of the semiconductor chip 12 and explained above.

### Second Embodiment

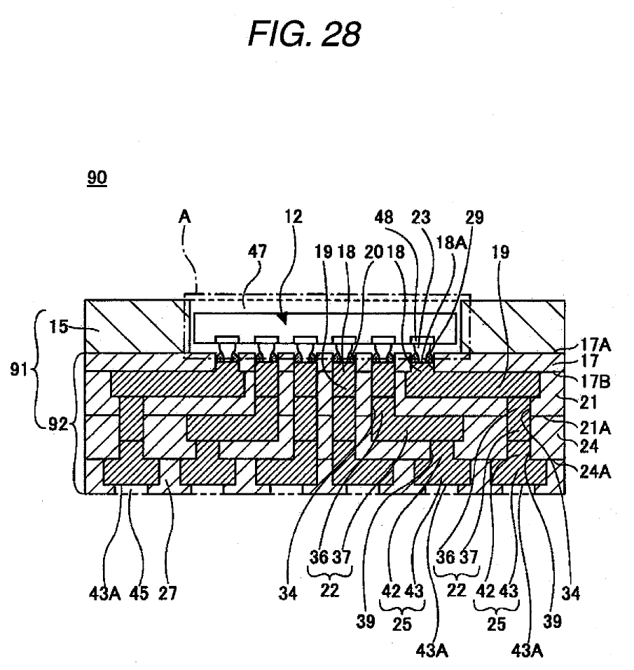

FIG. 28 is a sectional view of a semiconductor device (semiconductor package) according to a second embodiment of the present invention. In FIG. 28, the same reference symbols are affixed to the same constituent portions as those of the semiconductor device 10 in the first embodiment.

By reference to FIG. 28, a semiconductor device 90 of the second embodiment is constructed similarly to the semiconductor device 10, except that a wiring substrate 91 is provided instead of the wiring substrate 11 provided to the semiconductor device 10 in the first embodiment.

The wiring substrate 91 is constructed similarly to the wiring substrate 11, except that a multilayer wiring structure 92 is provided instead of the multilayer wiring structure 14 provided to the wiring substrate 11. The multilayer wiring structure 92 is constructed similarly to the multilayer wiring structure 14, except that a thickness of the chip connection pads 18 is reduced and the solder 20 is provided to a part of the through hole 29 (in other words, the solder 20 is provided between the insulating layers 17).

The semiconductor device 90 constructed in this manner in the second embodiment can achieve the similar advantages to those of the semiconductor device 10 of the first embodiment.

Also, a portion of the insulating layer 17 positioned between the through holes 29 functions as the solder resist layer. Therefore, it can be prevented that neighboring solders 20 come into contact with each other. In particular, this structure is effective to the case where the semiconductor device 12 on which the electrode pads 48 are arranged at a narrow pitch is mounted on the multilayer wiring structure 92.

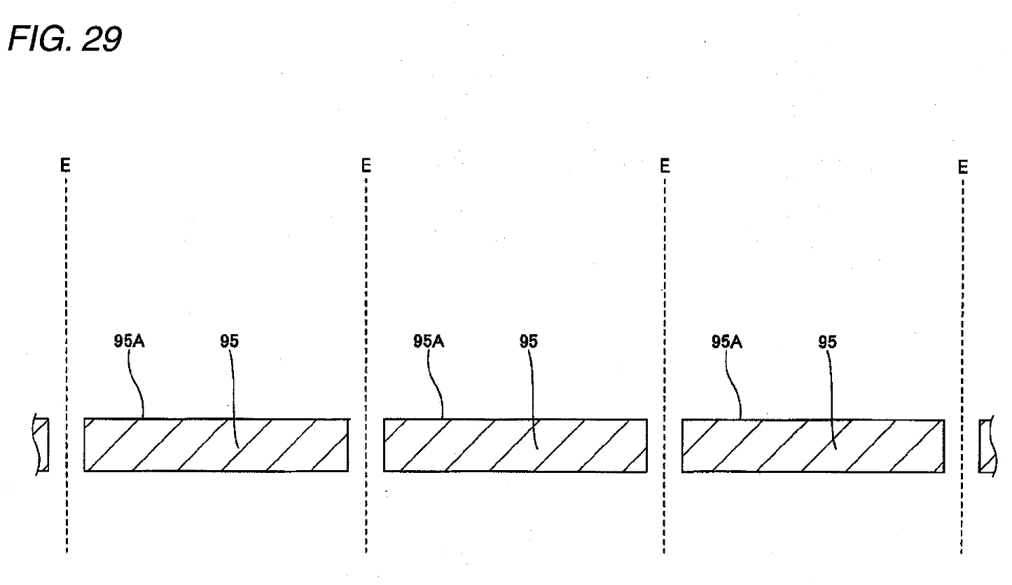

FIG. 29 to FIG. 37 are views showing steps of manufacturing the semiconductor device according to the second embodiment of the present invention. In FIG. 29 to FIG. 37, the same reference symbols are affixed to the same constituent portions as those of the semiconductor device 90 in the second exemplary embodiment.

A method of manufacturing the semiconductor device 90 of the second exemplary embodiment will be explained with reference to FIG. 29 to FIG. 37 hereunder. At first, in steps shown in FIG. 29, the substrate 55 explained in the first embodiment and shown in FIG. 4 is cut along the cutting position E respectively. Thus, a plurality of convex portions 95 of a support 97 described later are formed. Upper surfaces 95A of a plurality of convex portions 95 are made flat.

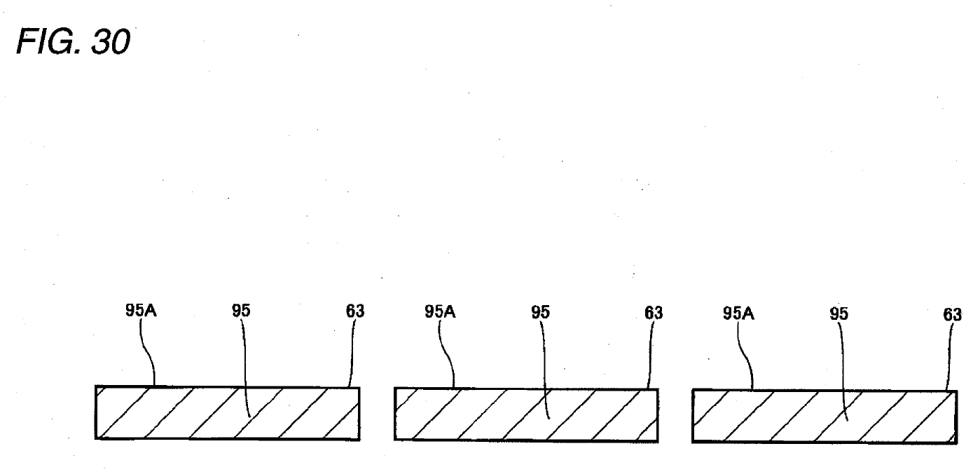

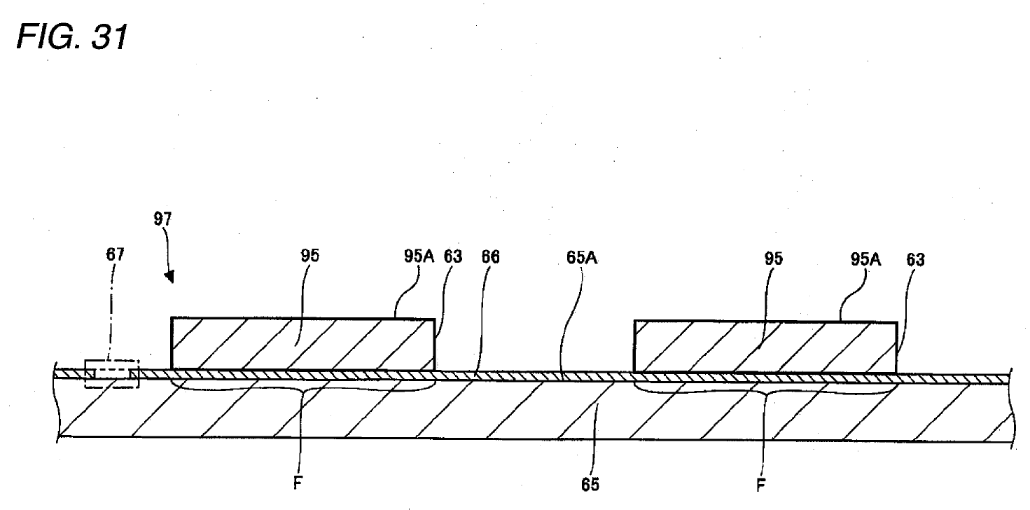

Then, in steps shown in FIG. 30, the metal film 63 is formed to cover the overall surfaces of the convex portions 95. Then, in steps shown in FIG. 31, the convex portions 95 each formed with metal film 63 are adhered onto the metal film 66 formed on the portions that correspond to the convex portion providing areas F of the structure explained in the first embodiment and shown in FIG. 11, and then the metal film 63 formed on the convex portions 95 is electrically connected to the metal film 66 formed on the supporting substrate 65. Accordingly, the support 97 is formed which includes a plurality of convex portions 95 each formed with the metal film 63 and the supporting substrate 65 formed with the metal film 66.

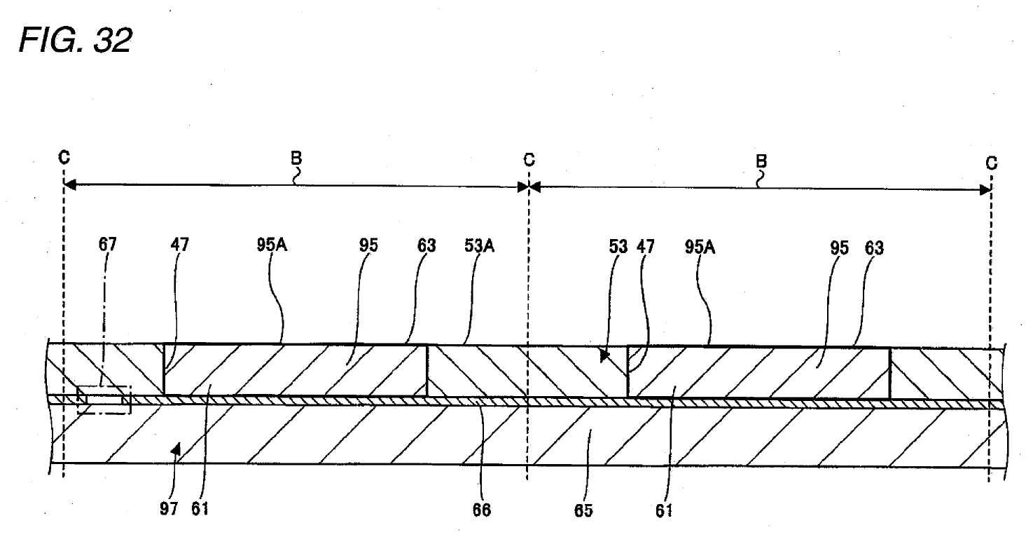

Then, in steps shown in FIG. 32, the convex portions 95 each formed with the metal film 63 are inserted into the through holes formed in the stiffener base material 53, and thus the stiffener base material 53 is tentatively adhered to the support 97 (tentatively adhering step). Accordingly, the upper surfaces of the metal films 63 provided on the upper surfaces 95A of the convex portions 95 are flush with the upper surface 53A of the stiffener base material 53. Upon tentatively adhering the stiffener base material 53 to the support 97, for example, the double faced tape of thermally peelable type can be employed.

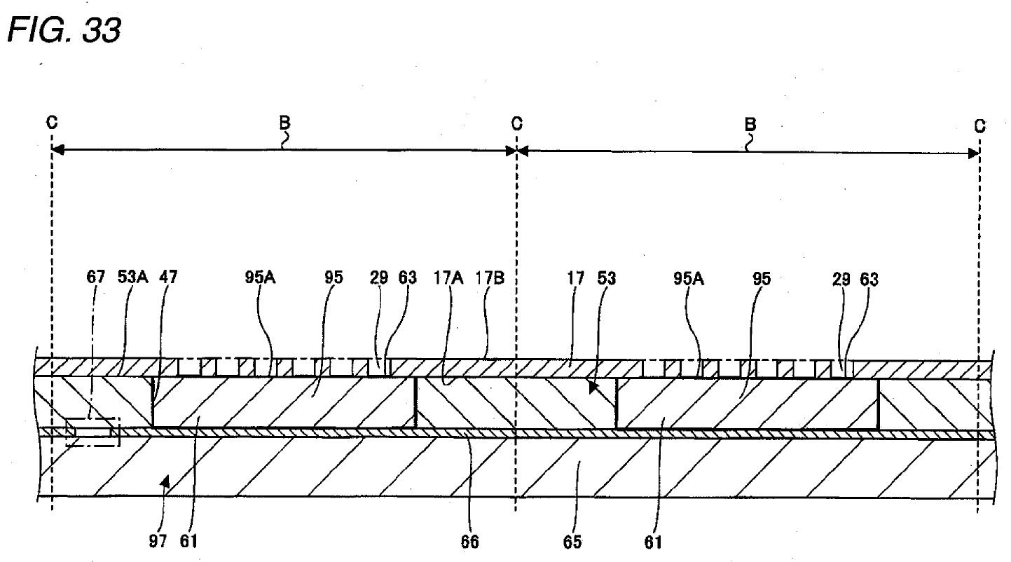

Then, in steps shown in FIG. 33, the insulating layer 17 in which a plurality of through holes 29 are provided is formed on the structure shown in FIG. 32. At this time, the through holes 29 are formed to expose the portion of the metal film 63 corresponding to the forming area of the solder 20 respectively. The insulating layer 17 is formed by the similar process to the steps explained in the first exemplary embodiment and shown in FIG. 14.

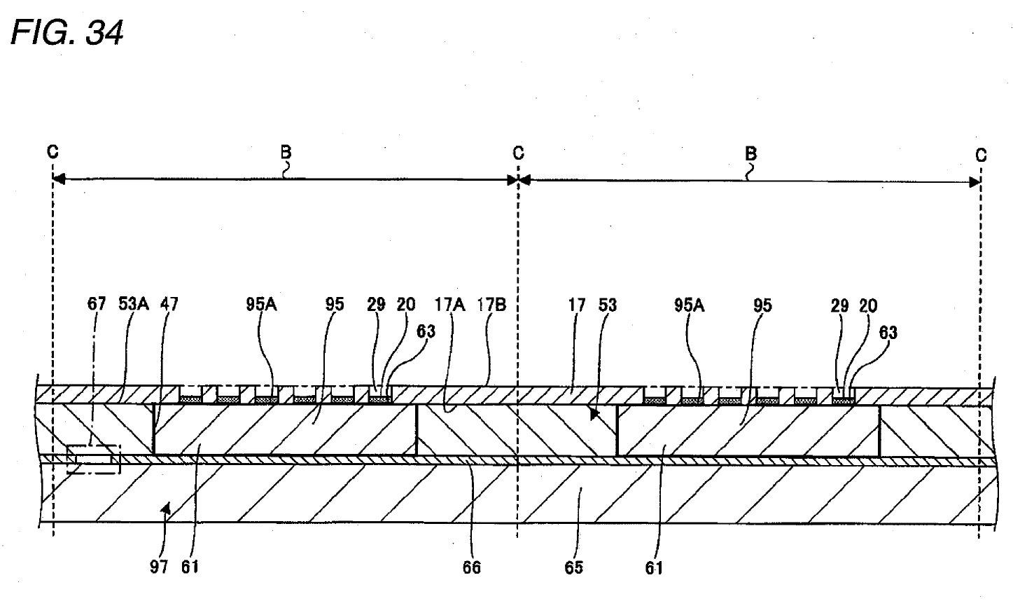

Then, in steps shown in FIG. 34, the solder 20 is formed on the portions of the metal film 63 exposed from the through holes 29, by the electroplating process using the metal films 63, 66 as a power feeding layer. As the solder 20, for example, Sn—Ag—Cu based solder, Sn—Zn—Bi based solder, Sn—Ag—In—Bi based solder, Sn—Ag—Cu—Ni based solder, Sn—Cu based solder, In based solder can be employed. Also, a thickness of the solder 20 can be set to 1 μm to 20 μm, for example.

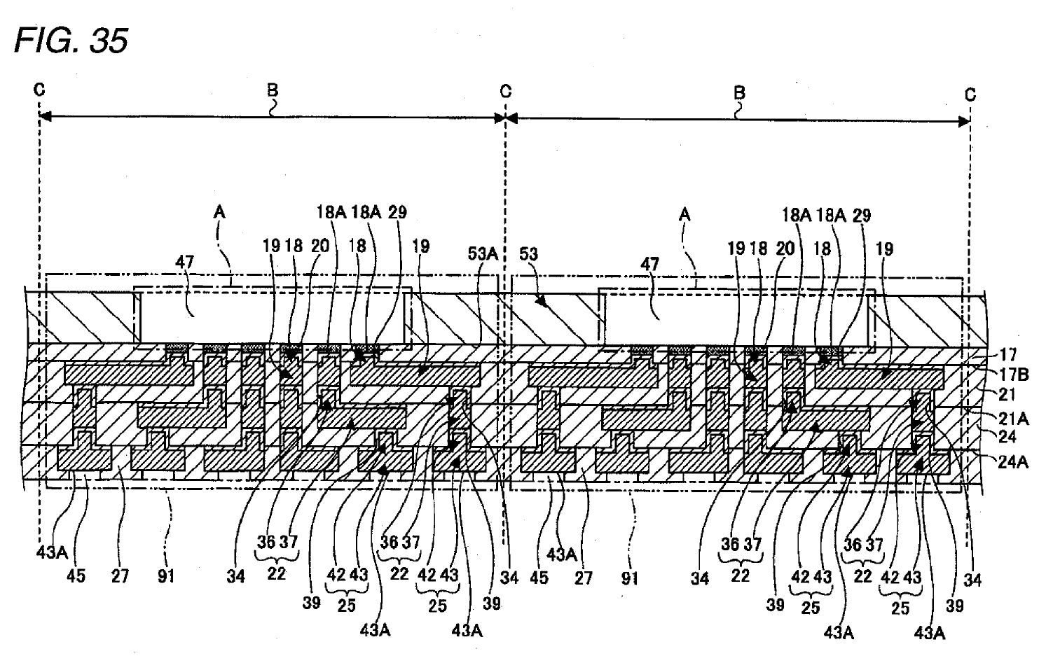

Then, in steps shown in FIG. 35, a plurality of wiring substrates 91 that are not diced into individual pieces are formed by applying the processes similar to the steps explained in the first exemplary embodiment and shown in FIG. 16 to FIG. 23. Then, a plurality of wiring substrates 91 that are not diced into individual pieces are turned upside down.

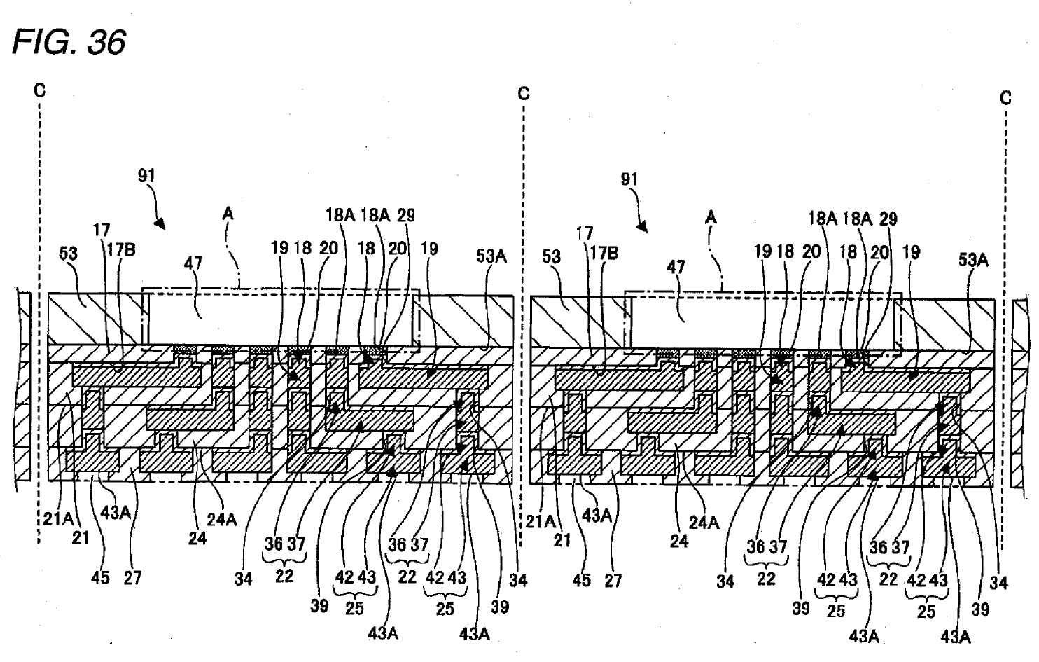

Then, in steps shown in FIG. 36, the multilayer wiring structures 92 and the stiffener 15 are divided into individual pieces by cutting the structure shown in FIG. 35 along the cutting position C respectively (cutting step). Accordingly, a plurality of wiring substrates 91 are diced into individual pieces.

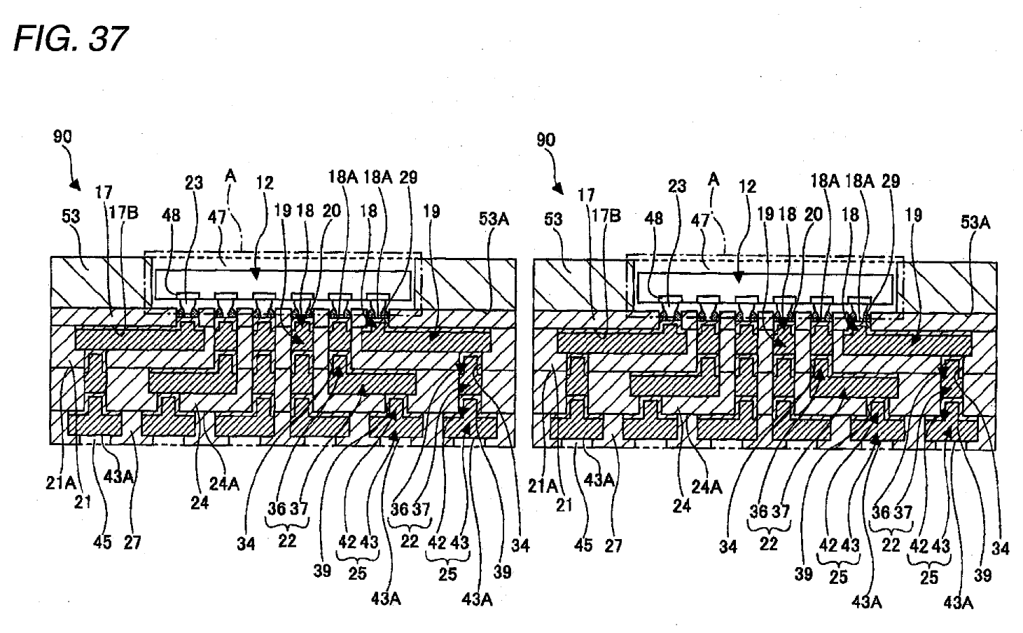

Then, in steps shown in FIG. 37, the semiconductor chip 12 having the electrode pads 48 each connected to the bump 23 thereon is flip-chip mounted on the chip connecting pads 18 provided to the multilayer wiring structure 92. Accordingly, the semiconductor device 90 of the second exemplary embodiment is manufactured.

According to the method of manufacturing the semiconductor device of the present embodiment, steps of forming the concave portions 59 to provide the solder 20 on the upper surface 95A side of the convex portion 95 respectively are eliminated. Therefore, a manufacturing cost of the semiconductor device 90 can be reduced.

Also, the solder 20 is formed in the through holes 29 in the insulating layer 27 respectively. Therefore, such a situation can be prevented that, in flip-chip mounting the semiconductor chip 12 onto the chip connecting pads 18 provided on the multilayer wiring structure 92, the neighboring solders 20 come into contact with each other to form a short-circuit.

The method of manufacturing the semiconductor device 90 of the present embodiment can achieve the similar advantages to the method of manufacturing the semiconductor device 10 in the first exemplary embodiment.

In this case, in the present embodiment the case where the solder 20 is formed by the electroplating process is explained by way of example. But the solder 20 may be formed by the ink jet method. In this case, the process in steps shown in FIG. 30 is not needed, and therefore a manufacturing cost of the semiconductor device 90 can be further lowered.

Also, in the present embodiment, the case where the semiconductor device 90 is manufactured by using the support 97 in which the convex portions 95 and the supporting substrate 65 are formed as the separate body is explained by way of example. But the semiconductor device 90 may be manufactured by using the support in which the convex portions 95 and the supporting substrate 65 are integrally formed.

Also, in the present embodiment, the case where the semiconductor device 90 is manufactured by using the stiffener base material 53 is explained by way of example. But the semiconductor device 90 may be manufactured by using the stiffener base material 79 (see FIG. 27) explained in the first exemplary embodiment instead of the stiffener base material 53.

Also, in the present embodiment, the case where the solders 20 are formed on the metal film 63 in steps shown in FIG. 34 is explained by way of example. But the pads formed of the metal other than the solder may be provided instead of the solder 20. Concretely, the gold layer, the nickel layer, and the copper layer are formed sequentially on the metal film 63 by the electroplating process, and then the support is removed after the multiplayer wiring structure is formed. Thus, the pads each consisting of the gold layer, the nickel layer, and the copper layer are formed. When the semiconductor chip 12 is mounted on the wiring substrate on which such pads are provided, the solder paste is formed on the pad surfaces in advance and then the semiconductor chip 12 is flip-chip mounted on the wiring substrate.

While the present invention has been shown and described with reference to certain exemplary embodiments thereof, it will be understood by those skilled in the art that various changes in form and details may be made therein without departing from the spirit and scope of the invention as defined by the appended claims. It is aimed, therefore, to cover in the appended claim all such changes and modifications as fall within the true spirit and scope of the present invention.

What is claimed is:

1. A wiring substrate, comprising:
a multilayer wiring structure comprising:
a plurality of insulating layers;
a plurality of wiring patterns; and
a plurality of chip mounting pads which are electrically connected to the wiring patterns and on which a semiconductor chip is flip-chip mounted; and
a stiffener provided on a portion of the multilayer wiring structure, which is outside of a mounting area on which the semiconductor chip is flip-chip mounted, wherein a thermal expansion coefficient of the stiffener is substantially equal to that of the semiconductor chip.

2. The wiring substrate according to claim 1, wherein the stiffener is formed of at least one of materials selected from silicon, Carbon Fiber Reinforced Plastic (CFRP), and invar.

3. A semiconductor device, comprising:
a semiconductor chip; and
a wiring substrate comprising:
a multilayer wiring structure comprising:
a plurality of insulating layers;
a plurality of wiring patterns; and
a plurality of chip mounting pads which are electrically connected to the wiring patterns and on which the semiconductor chip is flip-chip mounted, and
a stiffener provided on a portion of the multilayer wiring structure, which is outside of a mounting area on which the semiconductor chip is flip-chip mounted, wherein a thermal expansion coefficient of the stiffener is substantially equal to that of the semiconductor chip.

4. The semiconductor device according to claim 3, wherein the stiffener is formed of at least one of materials selected from silicon, Carbon Fiber Reinforced Plastic (CFRP), and invar.

5. A method of manufacturing a wiring substrate including a stiffener, the method comprising:
(a) forming a stiffener base material whose thermal expansion coefficient is substantially equal to that of a semiconductor chip and which has a through portion therein;
(b) forming a support which has a convex portion corresponding to a shape of the through portion and whose thermal expansion coefficient is substantially equal to that of the semiconductor chip;
(c) tentatively adhering the stiffener base material to the support by inserting the convex portion into the through portion;
(d) forming a multilayer wiring structure over the convex portion and the stiffener base material; and
(e) removing the support from the stiffener base material after step (d).

6. The method according to claim 5, wherein the stiffener is formed of at least one of materials selected from silicon, Carbon Fiber Reinforced Plastic (CFRP), and invar.

7. The method according to claim 5, wherein the support is formed of at least one of materials selected from silicon, Carbon Fiber Reinforced Plastic (CFRP), and invar.

8. A method of manufacturing wiring substrates, the method comprising:
(a) forming a stiffener base material whose thermal expansion coefficient is substantially equal to that of a semiconductor chip and which has a plurality of through portions therein;
(b) forming a support which has a plurality of convex portions each corresponding to a shape of a corresponding one of the through portions and whose thermal expansion coefficient is substantially equal to that of the semiconductor chip;
(c) tentatively adhering the stiffener base material to the support by inserting the convex portions into the through portions;
(d) forming a multilayer wiring structure over the convex portions and the stiffener base material;
(e) removing the support from the stiffener base material after step (d); and
(f) cutting the stiffener base material and the multilayer wiring structure after step (e), thereby forming the wiring substrates.

9. The method according to claim 5, wherein the through portion is broadened in width from an upper surface of the convex portion toward a lower surface of the convex portion in a state that the convex portion is inserted into the through portion.

10. A method of manufacturing a semiconductor device, comprising:
flip-chip mounting a semiconductor chip on the wiring substrate manufactured according to the method of claim 5.

11. The method according to claim 5, wherein the thermal expansion coefficients of the stiffener base material and the support are about 1 to 5 ppm/° C.

12. The method according to claim 8, wherein the thermal expansion coefficients of the stiffener base material and the support are about 1 to 5 ppm/° C.
